(19) United States
(12) Patent Application Publication
(10) Pub. No.: US 2025/0130185 A1
(43) Pub. Date: Apr. 24, 2025

(54) NON-DESTRUCTIVE THREE-DIMENSIONAL PROBING AND CHARACTERIZATION OF SPECIMENS

(71) Applicant: Applied Materials Israel Ltd., Rehovot (IL)

(72) Inventors: Uri Hadar, Tel-Aviv (IL); Doron Girmonsky, Raanana (IL); Dror Shemesh, Hod Hasharon (IL); Michal Eilon, Beit-Elazari (IL)

(73) Assignee: Applied Materials Israel Ltd., Rehovot (IL)

(21) Appl. No.: 18/383,007

(22) Filed: Oct. 23, 2023

(51) Int. Cl. G01N 23/2252; G01B 15/02; G01B 15/04

(52) U.S. Cl. CPC G01N 23/2252; G01B 15/02; G01B 15/04; G01N 2223/304; G01N 2223/305; G01N 2223/633

(57) ABSTRACT

Disclosed herein is a system for non-destructive characterization of specimens. The system includes an electron beam (e-beam) source for projecting e-beams at one or more e-beam landing energies on a specimen; an X-ray detector for sensing X-rays emitted from the specimen, thereby obtaining measurement data; and a processing circuitry. The processing circuitry is configured to: (i) extract from the measurement data key features specified by a vector \vec{f}_{key}; and (ii) determine values \vec{p} of one or more structural parameters, characterizing the specimen, based on \vec{f}_{key} and a set of vectors of simulated key features {\vec{f}ₙ}ₙ₌₁^{N}. Each of the \vec{f}ₙ is a product of a computer simulation of emission of X-rays from a respective simulated specimen due to impinging thereof with e-beams at each of the one or more landing energies.

### TECHNICAL FIELD

The present disclosure relates generally to non-destructive three-dimensional probing and characterization of specimens based on X-ray measurements and computer simulation.

### BACKGROUND OF THE INVENTION

“Three-dimensional” structures are increasingly used in the semiconductor industry, particularly, in the manufacture of logic and memory components. Accordingly, as part of quality control, “three-dimensional” data of structures within specimens must typically be obtained. At present, most techniques for profiling of specimens, which include three-dimensional internal structures, are destructive, and may involve the extraction of lamellas, or shaving off of slices, from a specimen and subsequent inspection thereof using e.g., transmission electron microscopy (TEM). The challenge remains to develop non-destructive techniques for profiling specimens incorporating three-dimensional internal structures, which allow for high-volume manufacturing (HVM).

### BRIEF SUMMARY OF THE INVENTION

Aspects of the disclosure, according to some embodiments thereof, relate to non-destructive three-dimensional probing and characterization of specimens based on X-ray measurements and computer simulation. More specifically, but not exclusively, aspects of the disclosure, according to some embodiments thereof, relate to non-destructive three-dimensional probing and characterization of specimens based on measurement of characteristic X-rays and modeling (through extrapolation from the computer simulation), which does not necessitate ground truth data.

Thus, according to an aspect of some embodiments, there is provided a system for non-destructive characterization of specimens. The system includes an electron beam (e-beam) source for projecting e-beams at one or more e-beam landing energies on a specimen being tested, an X-ray detector for sensing X-rays emitted from the tested specimen (i.e., the specimen being tested), and a processing circuitry. The processing circuitry is configured to: (i) receive from the X-ray detector X-ray measurement data pertaining to one or more e-beam landing energies; (ii) extract from the X-ray measurement data a vector \vec{f}_{key} specifying values of key features of the X-ray measurement data; and (iii) determine values \vec{p}ₛ, pertaining to the tested structure and assumed by one or more structural parameters, based on \vec{f}_{key} and a set of vectors of simulated key features {\vec{f}ₙ}ₙ₌₁^{N}. For each 1≤n≤N, \vec{p}ₙ specifies values, pertaining to an n-th simulated specimen and assumed by the one or more structural parameters, and \vec{f}ₙ is a product of computer simulation of emission of X-rays from the n-th simulated specimen due to impinging thereof with e-beams at each of the one or more landing energies.

According to some embodiments of the system, the e-beam source and the X-ray detector form part of a scanning electron microscope.

According to some embodiments of the system, \vec{p}ₛ minimizes a loss function, which depends at least on \vec{f}_{key} and a vector valued function \vec{f}ₑₓₜ(\vec{p}) of the key features that is extrapolated from {\vec{f}ₙ}ₙ₌₁^{N}. According to some such embodiments, in addition to a first term dependent on \vec{f}_{key} and \vec{f}ₑₓₜ(\vec{p}), the loss function additionally includes at least one regularizing term, which is a function of \vec{p}.

According to some embodiments of the system, the processing circuitry is configured to execute an optimization algorithm in order to minimize the loss function and thereby determine \vec{p}ₛ.

According to some embodiments of the system, the processing circuitry is configured to determine \vec{p}ₛ by computing a minimum (mathematical) distance between \vec{f}_{key} and \vec{f}ₑₓₜ(\vec{p}). \vec{f}ₑₓₜ(\vec{p}) is a vector valued function of key features extrapolated from {\vec{f}ₙ}ₙ₌₁^{N}.

According to some embodiments of the system, the processing circuitry is configured to determine \vec{p}ₛ by computing (mathematical) distances between \vec{f}_{key} and the \vec{f}ₙ.

According to some embodiments of the system, for each 1≤n≤N, \vec{p}ₙ=\vec{p}₀+\vec{δ}ₙ. \vec{p}₀ specifies nominal values of the one or more structural parameters. The \vec{δ}ₙ sample a hypervolume centered about \vec{p}₀ in a K-dimensional vector space defined by the one or more structural parameters with K being the number of the one or more structural parameters. The size and boundaries of the hypervolume are selected so as to encompass the expected variations of the one or more structural parameters.

According to some embodiments of the system, the one or more structural parameters include any geometrical and/or compositional parameter characterizing the specimen whose modification impacts at least some of the values of the key features.

According to some embodiments of the system, the one or more structural parameters include one or more of an overall concentration of at least one material (i.e., substance) that the tested specimen includes, and, optionally, when the tested specimen includes a structure embedded therein or thereon, a width of the embedded structure.

According to some embodiments of the system, the tested specimen includes a plurality of layers.

According to some embodiments of the system, the one or more structural parameters include one or more of (i) at least one thickness of at least one of the layers, respectively, (ii) a combined thickness of at least two or more of the layers, (iii) at least one mass density of at least one of the layers, respectively, and (vi) at least one relative concentration of at least one material, respectively, in one or more of the layers.

According to some embodiments of the system, the one or more e-beam landing energies are such that induced is emission of X-rays about one or more characteristic X-ray lines pertaining to one or more target substances (materials), respectively, which the tested specimen includes.

According to some embodiments of the system, the one or more e-beam landing energies are such that induced is emission of X-rays originating from each of at least two of the plurality of layers.

According to some embodiments of the system, the X-ray detector is configured to sense at least one measured spectrum of the respectively emitted X-rays in at least one photon energy range, respectively, which includes at least one of the characteristic X-ray lines. The X-ray measurement data include the measured spectra.

According to some embodiments of the system, the key features are, include, or are functions of intensities of the characteristic X-ray lines and/or intensities of background radiation.

According to some embodiments of the system, the key features are, or include, the intensities of the characteristic X-ray lines, each normalized by a mean of the background intensity about the respective characteristic X-ray line.

According to some embodiments of the system,

$${\vec{p}}_{s} = {arg min}_{\vec{p}} ‖ {\vec{f}}_{key} - {\vec{f}}_{ext} ( \vec{p} ) ‖$$

with the double vertical bars denoting a vector norm.

According to some embodiments of the system,

$${\vec{p}}_{s} = {arg min}_{\vec{p}} ( ‖ {\vec{f}}_{key} - {\vec{f}}_{ext} ( \vec{p} ) ‖ + R ( \vec{p} ) ) .$$

R(\vec{p}) is a regularizing term(s). The double vertical bars denote a vector norm.

According to some embodiments of the system, \vec{f}ₑₓₜ(\vec{p})=\vec{f}ₑₓₜ(\vec{p}₀+\vec{δ})=\vec{f}₀+A\vec{δ} with \vec{p}₀ specifying nominal values of the one or more structural parameters, \vec{δ} specifying deviations from the nominal values, \vec{f}₀ being a vector of values of the key features corresponding to \vec{p}₀, and A being a matrix.

According to some embodiments of the system, \vec{f}₀ is a product of computer simulation of emission of X-rays from a simulated specimen, which is characterized by \vec{p}₀, due to impinging thereof with e-beams at each of the one or more landing energies. The matrix A equals

$${arg min}_{B} ‖ ( \begin{matrix}{( {\vec{f}}_{{\vec{p}}_{1}} - {\vec{f}}_{0} - B {\vec{δ}}_{1} )}^{T} \\ {( {\vec{f}}_{{\vec{p}}_{2}} - {\vec{f}}_{0} - B {\vec{δ}}_{2} )}^{T} \\ ⋮ \\ {( {\vec{f}}_{{\vec{p}}_{N}} - {\vec{f}}_{0} - B {\vec{δ}}_{N} )}^{T}\end{matrix} ) ‖$$

with the double vertical bars denoting a matrix norm and, for each 1≤n≤N, \vec{δ}ₙ=\vec{p}ₙ−\vec{p}₀.

According to some embodiments of the system, \vec{f}₀ and the matrix A are obtained as the solution of

$${arg min}_{\vec{g} , B} ‖ ( \begin{matrix}{( {\vec{f}}_{{\vec{p}}_{1}} - \vec{g} - B {\vec{δ}}_{1} )}^{T} \\ {( {\vec{f}}_{{\vec{p}}_{2}} - \vec{g} - B {\vec{δ}}_{2} )}^{T} \\ ⋮ \\ {( {\vec{f}}_{{\vec{p}}_{N}} - \vec{g} - B {\vec{δ}}_{N} )}^{T}\end{matrix} ) ‖$$

with the double vertical bars denoting a matrix norm and, for each 1≤n≤N, \vec{δ}ₙ=\vec{p}ₙ−\vec{p}₀.

According to some embodiments of the system, the processing circuitry is configured to, as part of determining \vec{p}ₛ, apply a k-nearest neighbor (k-NN) regression algorithm to \vec{f}_{key} with respect to {\vec{f}ₙ}ₙ₌₁^{N} in order to determine k of the \vec{f}ₙ, which are closest to \vec{f}_{key}.

According to some embodiments of the system, \vec{p}ₛ is the average, optionally, weighted, or the median of the \vec{p}ₙ corresponding to the k closest \vec{f}ₙ (i.e., the k \vec{f}ₙ closest to \vec{f}_{key}).

According to some embodiments of the system, wherein the processing circuitry is configured to determine \vec{p}ₛ by computing the minimum (mathematical) distance between \vec{f}_{key} and \vec{f}ₑₓₜ(\vec{p}), the processing circuitry is further configured to obtain {\vec{f}ₙ}ₙ₌₁^{N} by subjecting \vec{f}_{key} to an (k=N)−NN classifier with respect to a set of N′>N vectors of key features, which includes the \vec{f}ₙ, and whose other N′−N vectors are obtained by applying the computer simulation with respect to N′−N additional simulated specimens.

According to some embodiments of the system, in order to derive the intensities of the characteristic X-ray lines, the processing circuitry is configured to fit a free curve onto each interval of the measured spectra, which is about (i.e., substantially) centered about a respective characteristic X-ray line and constituted by a vicinity of the characteristic X-ray line, thereby obtaining a respective optimized curve.

According to some embodiments of the system, the free curve is proportional to a bulge-shaped function, or wherein the free curve is a sum of functions, which includes a bulge-shaped function. The processing circuitry is configured to, as part of the fitting of the free curve, fit the bulge-shaped function onto a peak about the characteristic X-ray line of the respective measured spectrum.

According to some embodiments of the system, the sum of functions includes a second function (i.e., in addition to the bulge-shaped function), which is a polynomial. In fitting the free curve the processing circuitry fits the second function so as to account for a background intensity component of the respective measured spectrum.

According to some embodiments of the system, the processing circuitry is configured to derive the \vec{f}ₙ through computer simulation of emission of X-rays from the respective simulated specimen due to the impinging thereof with e-beams at each of the one or more e-beam landing energies.

According to some embodiments of the system, the processing circuitry is further configured to extrapolate \vec{f}ₑₓₜ(\vec{p}) from the {\vec{f}ₙ}ₙ₌₁^{N}.

According to some embodiments of the system, the X-ray detector is an energy-dispersive X-ray spectrometer or a wavelength-dispersive X-ray spectrometer.

According to some embodiments of the system, the tested specimen is a patterned wafer, or a part of patterned wafer, optionally, in one of the fabrication stages thereof.

According to an aspect of some embodiments, there is provided a method for non-destructive characterization of specimens. The method includes a measurement operation and a measurement data analysis operation. The measurement operation includes, for each of one or more landing energies, suboperations of projecting an e-beam on a tested specimen, and obtaining (X-ray) measurement data by measuring intensity of X-rays emitted from the tested specimen due to penetration of the e-beam thereinto. The measurement data analysis operation includes suboperations of extracting from the measurement data a vector \vec{f}_{key} specifying values of key features, and determining values \vec{p}ₛ, pertaining to the tested structure and assumed by one or more structural parameters, based on \vec{f}_{key} and a set of vectors of simulated key features {\vec{f}ₙ}ₙ₌₁^{N}. For each 1≤n≤N, \vec{p}ₙ specifies values pertaining to an n-th simulated specimen and assumed by the one or more structural parameters, and each of the \vec{f}ₙ is obtained through computer simulation of emission of X-rays from the n-th simulated specimen, due to impinging thereof with e-beams at each of the one or more landing energies.

According to some embodiments of the method, \vec{p}ₛ minimizes a loss function, which is a function of at least \vec{f}_{key} and a vector valued function \vec{f}ₑₓ(\vec{p}) of the key features that is extrapolated from {\vec{f}ₙ}ₙ₌₁^{N}. According to some such embodiments, in addition to a first term dependent on \vec{f}_{key} and \vec{f}ₑₓₜ(\vec{p}), the loss function additionally includes a regularizing term(s).

According to some embodiments of the method, \vec{p}ₛ is determined by executing an optimization algorithm, which is configured to minimize the loss function.

According to some embodiments of the method, \vec{p}ₛ is determined by computing a minimum (mathematical) distance between \vec{f}_{key} and \vec{f}ₑₓₜ(\vec{p}), which is a vector valued function of key features extrapolated from {\vec{f}ₙ}ₙ₌₁^{N}.

According to some embodiments of the method, \vec{p}ₛ is determined by computing (mathematical) distances between \vec{f}_{key} and the \vec{f}ₙ.

According to some embodiments of the method, for each 1≤n≤N, \vec{p}ₙ=\vec{p}₀+\vec{δ}ₙ. \vec{p}₀ specifies nominal values of the one or more structural parameters. The \vec{δ}ₙ are selected to sample a hypervolume centered about \vec{p}₀ in a K-dimensional vector space defined by the one or more structural parameters with K being the number of the one or more structural parameters. The size and boundaries of the hypervolume are selected so as to encompass the expected variations of the one or more structural parameters.

According to some embodiments of the method, the one or more structural parameters include any geometrical and/or compositional parameter characterizing the specimen whose modification impacts at least some of the values of the key features.

According to some embodiments of the method, the one or more structural parameters include one or more of an overall concentration of at least one material (i.e., substance) that the tested specimen includes, and, optionally, when the tested specimen includes a structure embedded therein or thereon, a width of the embedded structure.

According to some embodiments of the method, the tested specimen includes a plurality of layers.

According to some embodiments of the method, the one or more structural parameters include one or more of (i) at least one thickness of at least one of the layers, respectively, (ii) a combined thickness of at least two or more of the layers, (iii) at least one mass density of at least one of the layers, respectively, and (vi) at least one relative concentration of at least one material, respectively, in one or more of the layers.

According to some embodiments of the method, the one or more landing energies are selected so as to induce emission of X-rays about one or more characteristic X-ray lines pertaining to one or more target substances (materials), respectively, which the tested specimen includes.

According to some embodiments of the method, the one or more landing energies are selected so as to induce emission of X-rays from each of at least two of the plurality of layers.

According to some embodiments of the method, in each implementation of the suboperations of projecting the e-beam and obtaining the measurement data, obtained is at least one measured spectrum of the respectively emitted X-rays in at least one photon energy range, respectively, which includes at least one of the characteristic X-ray lines. The measurement data includes the measured spectra.

According to some embodiments of the method, the key features are, include, or are obtained from, intensities of the characteristic X-ray lines, and/or intensities of background radiation.

According to some embodiments of the method, the key features are, or include, the intensities of the characteristic X-ray lines, each normalized by a mean of the background intensity about the respective characteristic X-ray line.

According to some embodiments of the method,

$${\vec{p}}_{s} = {arg min}_{\vec{p}} ‖ {\vec{f}}_{key} - {\vec{f}}_{ext} ( \vec{p} ) ‖$$

with the double vertical bars denoting a vector norm.

According to some embodiments of the method,

$${\vec{p}}_{s} = {arg min}_{\vec{p}} ( ‖ {\vec{f}}_{key} - {\vec{f}}_{ext} ( \vec{p} ) ‖ + R ( \vec{p} ) ) .$$

R(\vec{p}) is a regularizing term(s). The double vertical bars denote a vector norm.

According to some embodiments of the method, \vec{f}ₑₓₜ(\vec{p})=\vec{f}ₑₓₜ(\vec{p}₀+\vec{δ})=\vec{f}₀+A\vec{δ} with \vec{p}₀ specifying nominal values of the one or more structural parameters, \vec{δ} specifying deviations from the nominal values, \vec{f}₀ being a vector of values of the key features corresponding to \vec{p}₀, and A being a matrix.

According to some embodiments of the method, \vec{f}₀ is a obtained through computer simulation of emission of X-rays from a simulated specimen, which is characterized by \vec{p}₀, due to impinging thereof with e-beams at each of the one or more landing energies. The matrix A equals

$${arg min}_{B} ‖ ( \begin{matrix}{( {\vec{f}}_{{\vec{p}}_{1}} - {\vec{f}}_{0} - B {\vec{δ}}_{1} )}^{T} \\ {( {\vec{f}}_{{\vec{p}}_{2}} - {\vec{f}}_{0} - B {\vec{δ}}_{2} )}^{T} \\ ⋮ \\ {( {\vec{f}}_{{\vec{p}}_{N}} - {\vec{f}}_{0} - B {\vec{δ}}_{N} )}^{T}\end{matrix} ) ‖$$

with the double vertical bars denoting a matrix norm and, for each 1≤n≤N, \vec{δ}ₙ=\vec{p}ₙ−\vec{p}₀.

According to some embodiments of the method, \vec{f}₀ and the matrix A are obtained as the solution of

$${arg min}_{\vec{g} , B} ‖ ( \begin{matrix}{( {\vec{f}}_{{\vec{p}}_{1}} - \vec{g} - B {\vec{δ}}_{1} )}^{T} \\ {( {\vec{f}}_{{\vec{p}}_{2}} - \vec{g} - B {\vec{δ}}_{2} )}^{T} \\ ⋮ \\ {( {\vec{f}}_{{\vec{p}}_{N}} - \vec{g} - B {\vec{δ}}_{N} )}^{T}\end{matrix} ) ‖$$

with the double vertical bars denoting a matrix norm and, for each 1≤n≤N, \vec{δ}ₙ=\vec{p}ₙ−\vec{p}₀.

According to some embodiments of the method, in the suboperation of determining \vec{p}ₛ, a k-nearest neighbor (k-NN) regression algorithm is applied to \vec{f}_{key} with respect to {\vec{f}ₙ}ₙ₌₁^{N} in order to determine k of the \vec{f}ₙ, which are closest to \vec{f}_{key}.

According to some embodiments of the method, \vec{p}ₛ is obtained by computing an average, optionally, weighted, or a median of the \vec{p}ₙ corresponding to the k closest \vec{f}ₙ (i.e., the k \vec{f}ₙ closest to \vec{f}₀).

According to some embodiments of the method, the measurement data analysis operation further includes, prior to the determining \vec{p}ₛ, a suboperation of obtaining {\vec{f}ₙ}ₙ₌₁^{N} by subjecting \vec{f}_{key} to an (k=N)−NN classifier with respect to a set of N′>N vectors of key features, which includes the \vec{f}ₙ, and whose other N′−N vectors are obtained by applying the computer simulation with respect to N′−N additional simulated specimens.

According to some embodiments of the method, in order to derive the intensities of the characteristic X-ray lines, onto each interval of the measured spectra, which is about (i.e., substantially) centered about a respective characteristic X-ray line and constituted by a vicinity of the characteristic X-ray line, a free curve is fitted, thereby obtaining a respective optimized curve.

According to some embodiments of the method, the free curve is proportional to a bulge-shaped function, or wherein the free curve is a sum of functions, which includes a bulge-shaped function. In the fitting of the free curve, the bulge-shaped function is fitted onto a peak about the characteristic X-ray line of the respective measured spectrum.

According to some embodiments of the method, the sum of functions includes a second function (i.e., in addition to the bulge-shaped function), which is a polynomial. In the fitting of the free curve the second function is fitted so as to account for a background intensity component of the respective measured spectrum.

According to some embodiments of the method, the method further includes an initial operation of deriving the \vec{f}ₙ through computer simulation of emission of X-rays from the respective simulated specimen due to the impinging thereof with e-beams at each of the at least one landing energy.

According to some embodiments of the method, wherein \vec{p}ₛ is determined by computing a minimum (mathematical) distance between \vec{f}_{key} and \vec{f}ₑₓₜ(\vec{p}), the method further includes, following the initial operation, extrapolating \vec{f}ₑₓₜ(\vec{p}) from {\vec{f}ₙ}ₙ₌₁^{N}.

According to some embodiments of the method, the tested specimen is a patterned wafer, or a part of patterned wafer, optionally, in one of the fabrication stages thereof.

According to some embodiments of the method, the measurement operation is implemented using a scanning electron microscope.

According to an aspect of some embodiments, there is provided a non-transitory computer-readable storage medium. The storage medium stores instructions that cause a system for non-destructive characterization of specimens, such as the above-described system, to implement the above-described method with respect to a (tested) specimen.

According to an aspect of some embodiments, there is provided a non-transitory computer-readable storage medium. The storage medium stores instructions that cause one or more processors to: (i) extract from X-ray measurement data pertaining to a tested specimen a vector \vec{f}_{key} specifying values of key features, and (ii) determining values \vec{p}ₛ, pertaining to the tested structure and assumed by one or more structural parameters, based on \vec{f}_{key} and a set of vectors of simulated key features {\vec{f}ₙ}ₙ₌₁^{N}. For each 1≤n≤N, \vec{p}ₙ specifies values pertaining to an n-th simulated specimen and assumed by the one or more structural parameters, and each of the \vec{f}ₙ is a product of computer simulation of emission of X-rays from the n-th simulated specimen, due to impinging thereof with e-beams at each of the one or more landing energies. The X-ray measurement data is obtained by, for each of one or more landing energies, projecting an e-beam on a tested specimen, and measuring intensity of X-rays emitted from the tested specimen due to penetration of the e-beam thereinto.

Certain embodiments of the present disclosure may include some, all, or none of the above advantages. One or more other technical advantages may be readily apparent to those skilled in the art from the figures, descriptions, and claims included herein. Moreover, while specific advantages have been enumerated above, various embodiments may include all, some, or none of the enumerated advantages.

Unless otherwise defined, all technical and scientific terms used herein have the same meaning as commonly understood by one of ordinary skill in the art to which this disclosure pertains. In case of conflict, the patent specification, including definitions, governs. As used herein, the indefinite articles “a” and “an” mean “at least one” or “one or more” unless the context clearly dictates otherwise.

Unless specifically stated otherwise, as apparent from the disclosure, it is appreciated that, according to some embodiments, terms such as “processing”, “computing”, “calculating”, “determining”, “estimating”, “assessing”, “gauging” or the like, may refer to the action and/or processes of a computer or computing system, or similar electronic computing device, that manipulate and/or transform data, represented as physical (e.g. electronic) quantities within the computing system's registers and/or memories, into other data similarly represented as physical quantities within the computing system's memories, registers or other such information storage, transmission or display devices.

Embodiments of the present disclosure may include apparatuses for performing the operations herein. The apparatuses may be specially constructed for the desired purposes or may include a general-purpose computer(s) selectively activated or reconfigured by a computer program stored in the computer. Such a computer program may be stored in a computer readable storage medium, such as, but not limited to, any type of disk including floppy disks, optical disks, CD-ROMs, magnetic-optical disks, read-only memories (ROMs), random access memories (RAMs), electrically programmable read-only memories (EPROMs), electrically erasable and programmable read only memories (EEPROMs), magnetic or optical cards, flash memories, solid state drives (SSDs), or any other type of media suitable for storing electronic instructions, and capable of being coupled to a computer system bus.

The processes and displays presented herein are not inherently related to any particular computer or other apparatus. Various general-purpose systems may be used with programs in accordance with the teachings herein, or it may prove convenient to construct a more specialized apparatus to perform the desired method(s). The desired structure(s) for a variety of these systems appear from the description below. In addition, embodiments of the present disclosure are not described with reference to any particular programming language. It will be appreciated that a variety of programming languages may be used to implement the teachings of the present disclosure as described herein.

Aspects of the disclosure may be described in the general context of computer-executable instructions, such as program modules, being executed by a computer. Generally, program modules include routines, programs, objects, components, data structures, and so forth, which perform particular tasks or implement particular abstract data types. Disclosed embodiments may also be practiced in distributed computing environments where tasks are performed by remote processing devices that are linked through a communications network. In a distributed computing environment, program modules may be located in both local and remote computer storage media including memory storage devices.

### BRIEF DESCRIPTION OF THE DRAWINGS

Some embodiments of the disclosure are described herein with reference to the accompanying figures. The description, together with the figures, makes apparent to a person having ordinary skill in the art how some embodiments may be practiced. The figures are for the purpose of illustrative description and no attempt is made to show structural details of an embodiment in more detail than is necessary for a fundamental understanding of the disclosure. For the sake of clarity, some objects depicted in the figures are not drawn to scale. Moreover, two different objects in the same figure may be drawn to different scales. In particular, the scale of some objects may be greatly exaggerated as compared to other objects in the same figure.

In the figures:

FIG. 1 presents a flowchart of a method for non-destructive three-dimensional probing and characterization of specimens based on X-ray measurements and computer simulation, according to some embodiments;

FIGS. 2A to 2D schematically depict a specimen being depth-probed as part of characterization thereof in accordance with the method of FIG. 1, according to some embodiments;

FIG. 3 presents a flowchart of a measurement data analysis operation of the method of FIG. 1, according to some specific embodiments thereof;

FIG. 4A presents an X-ray emission spectrum of a specimen, which was obtained by implementing a measurement operation of the method of FIG. 1, according to some embodiments thereof;

FIG. 4B presents an optimized curve which was fitted onto the X-ray emission spectrum of FIG. 4A in accordance with specific embodiments of a measurement data analysis operation of the method of FIG. 1;

FIG. 4C presents the optimized curve of FIG. 4B superimposed on the X-ray emission spectrum of FIG. 4A;

FIG. 4D presents a fitted gaussian included in the optimized curve of FIG. 4B, according to some embodiments;

FIG. 4E presents a fitted polynomial included in the optimized curve of FIG. 4B, the fitted polynomial accounting for bremsstrahlung, according to some embodiments; and

FIG. 5 schematically depicts a system for non-destructive three-dimensional probing and characterization of specimens based on X-ray measurements and computer simulation, according to some embodiments.

### DETAILED DESCRIPTION OF THE INVENTION

The principles, uses, and implementations of the teachings herein may be better understood with reference to the accompanying description and figures. Upon perusal of the description and figures present herein, one skilled in the art will be able to implement the teachings herein without undue effort or experimentation. In the figures, same reference numerals refer to same parts throughout.

The present application, according to some embodiments thereof, is directed to methods and systems for non-destructive three-dimensional probing and characterization of specimens (e.g., semiconductor specimens). According to some embodiments, e-beams at each of a plurality of (e-beam) landing energies are projected on a specimen, which is to be depth-profiled. Each e-beam penetrates into the specimen and excites emission of characteristic X-rays therefrom (and accompanying bremsstrahlung, i.e., background radiation). The greater the e-beam landing energy, the greater the depth to which the e-beam penetrates the specimen.

The spectrum of the emitted X-rays depends on the internal geometry of the specimen and the material composition thereof, in particular, the distribution of each material (i.e., substance) making up the specimen. As an e-beam travels through a specimen, the e-beam “probes” different regions it traverses. The contribution of each traversed region to the spectrum of the emitted X-rays depends not only on the concentration of each material included in the traversed region but also on the energy of the e-beam on entry thereto, which, in turn, decreases with the depth.

The present application teaches how to characterize internal structural features of a specimen based on values of key features extracted from measured spectra of the specimen. The measured spectra may be analyzed using optimization tools based on computer simulation of the specimen and the measurement setup employed to obtain the measured spectra. Advantageously, the disclosed methods and systems do not necessitate ground truth data, which are costly and time-consuming to obtain. In particular, the time between the design of a semiconductor device and its testing and mass production may potentially thus be reduced.

As used herein, “e-beam” stands for “electron beam”. The term “characteristic X-rays regime” refers to a photon energy range (i.e., an energy range of a photon, or, equivalently, frequency range) within the X-ray spectrum, which includes characteristic X-ray lines.

As used herein the terms “bremsstrahlung” and “background radiation” are interchangeable.

### Methods

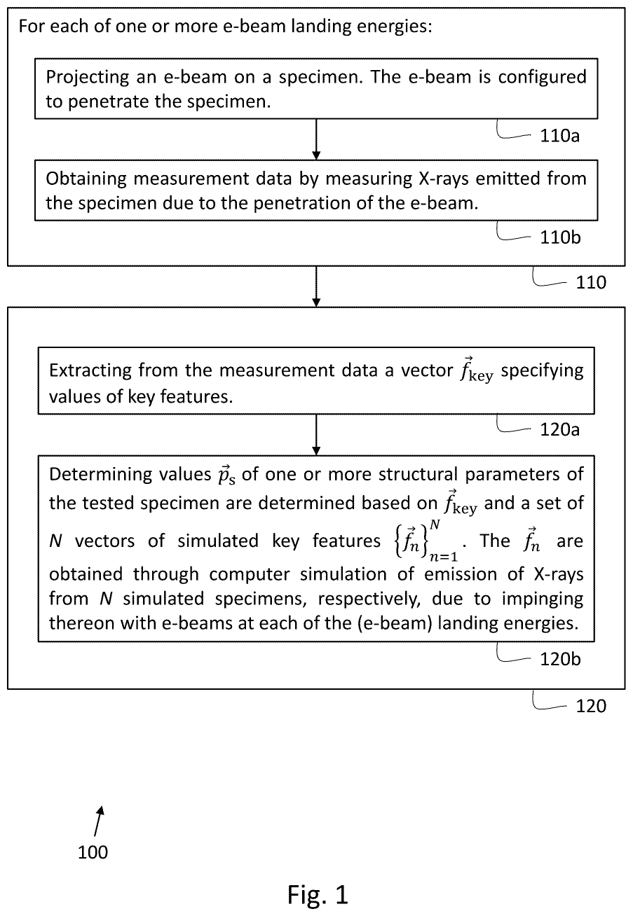

According to an aspect of some embodiments, there is provided a computerized method for non-destructive (three-dimensional) characterization of specimens (e.g. semiconductor structures) based on measurement of characteristic X-rays and computer simulation. FIG. 1 presents a flowchart of such a method, a method 100, according to some embodiments. Method 100 includes:
A measurement operation 110, which includes, for each of (one or more) e-beam landing energies (i.e., landing energies of the e-beams), performing:
   A suboperation 110a, wherein an e-beam is projected on a specimen (also referred to as “the tested specimen”).
   A suboperation 110b, wherein measurement data is obtained by measuring intensity of X-rays emitted from the tested specimen due to the penetration of the e-beam.
A data analysis operation 120 including:
   A suboperation 120a, wherein key features, specified by a vector \vec{f}_{key}, are extracted from the measurement data.
   A suboperation 120b, wherein values \vec{p}ₛ, pertaining to the tested specimen and assumed by one or more structural parameters, are determined based on \vec{f}_{key} and a set of vectors of simulated key features {\vec{f}ₙ}ₙ₌₁^{N}. The \vec{f}ₙ are obtained through computer simulation of emission of X-rays from N simulated specimens, respectively, due to impinging thereon with e-beams at each of the (e-beam) landing energies.

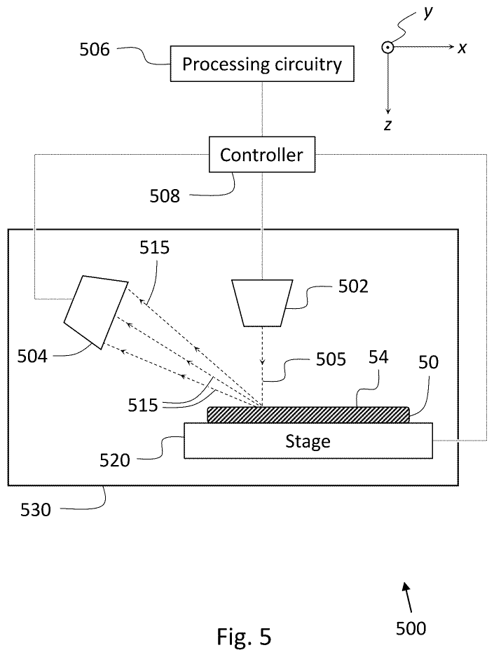

Method 100 may be implemented using a system, such as the system described below in the description of FIG. 5, or systems similar thereto. The term “extrapolation” is employed herein in an expansive manner and refers, generally, to the derivation of a continuous function from a plurality of data points.

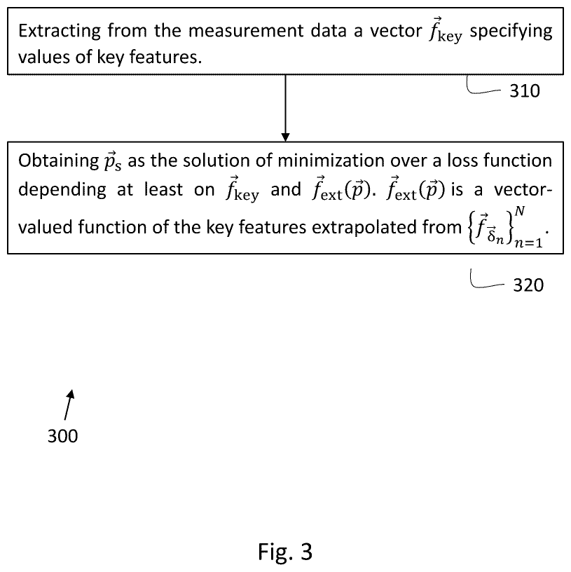

According to some embodiments, and as described in detail below in the description of FIG. 3, \vec{p}ₛ minimizes a loss function of \vec{f}_{key} and a vector valued function \vec{f}ₑₓₜ(\vec{p}) of the key features that is extrapolated from {\vec{f}ₙ}ₙ₌₁^{N}. According to some embodiments, apart from a first term which depends on both \vec{f}_{key} and \vec{f}ₑₓₜ(\vec{p}), the loss function may additionally include a regularizing term(s), e.g., in order to stabilize the solution or as a constraint(s) that reflects some prior knowledge about the one or more structural parameters. According to some embodiments, the first term corresponds to a mathematical distance between \vec{f}_{key} and \vec{f}ₑₓₜ(\vec{p}). According to some embodiments, standard local and/or global optimization tools may be used to minimize the loss function and thereby determine \vec{p}ₛ. Alternatively, according to some embodiments wherein the optimization problem, defined by the minimization over the loss function, admits a known analytical solution, \vec{p}ₛ may be computed directly from the (function defining the) analytical solution.

According to some embodiments, and as expanded on below, \vec{p}ₛ is determined by computing distances from \vec{f}_{key} to the \vec{f}ₙ.

According to some embodiments, the specimen includes two or more layers. According to some such embodiments, the one or more structural parameters characterize each of at least some of the two or more layers. According to some embodiments, the tested specimen is a patterned wafer, a part of a patterned wafer, or a semiconductor device embedded in or on a patterned wafer, optionally, in one of the fabrication stages of the patterned wafer. According to some embodiments, the tested specimen is or includes a structure including one or more semiconductor materials. According to some embodiments, the structure may be constructed as part of a manufacturing processes of semiconductor devices and/or components of semiconductor devices. According to some embodiments, the structure may be an assist structure, which is constructed as part of a manufacturing processes of semiconductor devices and/or components of semiconductor devices. According to some embodiments, the tested specimen may be or include one or more logic components (e.g., a fin FET (FinFET) and/or a gate-all-around (GAA) FET) and/or memory components (e.g., a dynamic RAM and/or a vertical NAND (V-NAND)), optionally, in one of the fabrication stages thereof.

According to some embodiments, the N simulated specimens may be selected so as to reflect the expected variation (e.g., due to manufacturing imperfections) of the one or more structural parameters between specimens (of the same intended design). In particular, the \vec{p}ₙ may be selected to “sample” a hypervolume centered about \vec{p}₀ in a Kₚ dimensional vector space defined by the one or more structural parameters. \vec{p}₀ may specify nominal values of the one or more structural parameters. Kₚ is the number of the structural parameters. The size and boundaries of the hypervolume may be selected so as to encompass the expected variation of the one or more structural parameters. According to some embodiments, the number of simulated specimens N is greater than 2Kₚ (or at least strictly greater than Kₚ). As a non-limiting example, according to some embodiments, the \vec{p}ₙ may be selected such that, in terms of deviations from nominal values \vec{δ}ₙ=\vec{p}ₙ−\vec{p}₀, the \vec{δ}ₙ include each vector in a set of 2Kₚ vectors {\vec{d}ₖ, −\vec{d}ₖ}ₖ₌₁^{K}^{ₚ}. For each 1≤k≤Kₚ, \vec{d}ₖ is about equal to σₖ\hat{ι}ₖ. σₖ is the expected standard deviation of the k-th structural parameter, and \hat{ι}k is a unit vector pointing along the k-th axis of the Kₚ dimensional vector space defined by the Kₚ structural parameters.

Parameters characterizing the e-beam, particularly the e-beam landing energies, are selected so as to induce in suboperation 110a emission of characteristic X-rays by particles (specifically, particles of at least one target substance) in a probed region centered about a respective depth, which depends on the e-beam landing energy. More precisely, each probed region may correspond to a respective volume of the tested specimen, wherein electrons from the respective e-beam may cause ejections of electrons in the inner shells of atoms (in the probed region), leaving each of these atoms with an inner shell vacancy. The inner shell vacancy may be filled through the relaxation of an outer shell electron to the inner shell. The relaxation may be accompanied by emission of a photon (having energy equal to the energy lost by the electron in transitioning from the outer shell to the inner shell).

According to some embodiments, the number of e-beam landing energies, and the minimum and maximum e-beam landing energies, may be selected to ensure that the tested specimen is probed over a range of depths. According to some such embodiments, the number of e-beam landing energies, and the minimum and maximum e-beam landing energies, may be selected to ensure that the tested specimen is probed all along the depth-dimension thereof.

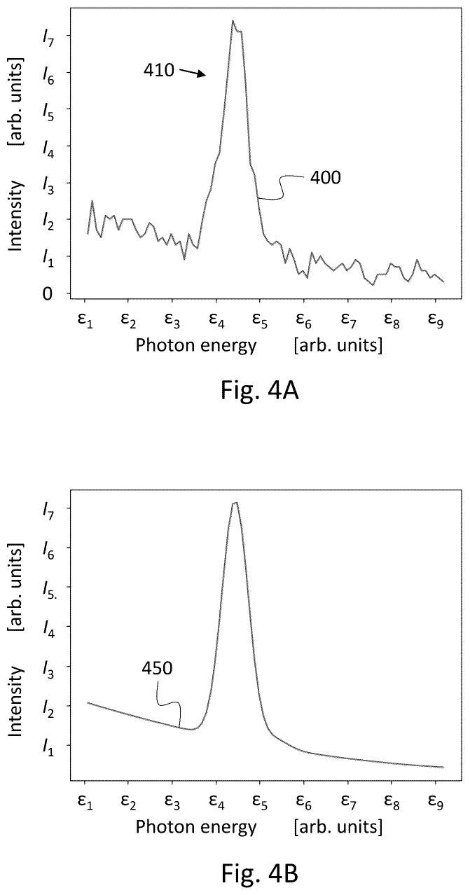

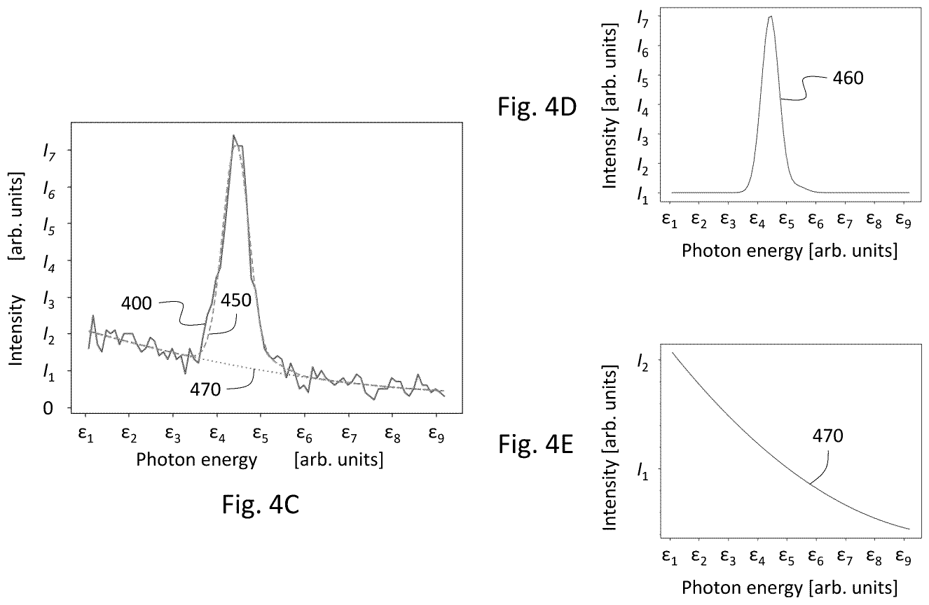

According to some embodiments, in each implementation of suboperation 110b, at least one measured spectrum is obtained. Each of the measured spectra may correspond to a photon energy range, or a respective photon energy range, which includes at least one characteristic X-ray line pertaining to at least one target substance, respectively. The measurement data includes (e.g., are constituted by) the measured spectra. According to some embodiments, \vec{f}_{key} is, includes, or is obtained from (i.e., is a function of) the measured spectra of characteristic X-ray lines. More specifically, according to some embodiments, each component of \vec{f}_{key} may be derived based on a set of extracted parameters characterizing the shape of a spectral peak about the respective characteristic X-ray line. According to some embodiments, the key features are, include, or are functions of intensities of the characteristic X-ray lines and/or intensities of background radiation. According to some embodiments, the key features include (e.g., are constituted by) the so-called “energy signature”. According to some embodiments, each component of the energy signature may correspond to an absolute, normalized, or relative intensity of a respective characteristic X-ray line. Each possibility corresponds to separate embodiments. According to some embodiments, each component of the energy signature may correspond to an intensity of a respective characteristic X-ray line normalized by a mean background intensity about the characteristic X-ray line. Various ways, whereby the energy signature may be derived, are described below in the description of FIGS. 4A-4E.

The values of the \vec{f}ₙ may be obtained through computer simulation. In an analogous manner to \vec{f}_{key}, each of the \vec{f}ₙ is, includes, or is obtained from (i.e., is a function of) respective simulated (instead of measured) spectral parameters characterizing the characteristic X-ray lines pertaining to the n-th simulated specimen. In particular, the \vec{f}ₙ and \vec{f}_{key} may share the same functional form (i.e., the same dependence on spectral parameters, such as the energy signature and, optionally, the background radiation). More precisely, in order to obtain the \vec{f}ₙ, the striking of e-beams at each of the at least one landing energy on each of the N (simulated) specimens, penetration thereof thereinto, and the resulting emission of X-rays, is simulated. Specifically, the computer simulation may simulate each of N implementations of measurement operation 110 with respect to each of the N simulated specimens. For each 1≤n≤N, the n-th simulated specimen is characterized by values \vec{p}ₙ of the one or more structural parameters. The computer simulation is configured to output the values of the key features corresponding to the simulated specimens, that is, \vec{f}ₙ for the n-th simulated specimen (i.e., characterized by \vec{p}ₙ).

According to some embodiments, the one or more structural parameters may include one or more of an overall concentration of at least one material that the tested specimen includes, and, optionally, when the tested specimen includes a structure embedded therein or thereon, a width of the embedded structure (e.g. the width of a gate, a fin, or a depletion layer). Additionally, or alternatively, according to some embodiments wherein the tested specimen includes one or more layers, the one or more structural parameters may include one or more of (i) at least one thickness of at least one of the layers, respectively, (ii) a combined thickness of at two or more of the layers, (iii) at least one mass density of at least one of the layers, respectively, and (iv) at least one relative concentration of at least one material, respectively, in one or more of the layers. By way of a non-limiting example, with respect to item (iv), the one or more structural parameters may include the relative concentration of a first material in a subset of the layers, e.g., adjacent layers or layers of a first type (potentially nonadjacent). The relative concentration of the first material in the subset (of the layers) may correspond to the overall number of particles of the first material, included in the subset, divided by the overall number of particles (of all materials, including the first material) included in the subset.

More generally, the one or more structural parameters may include any geometrical parameter and/or compositional parameter of the tested specimen whose modification impacts at least some of the components of \vec{f}_{key} in a measurable manner so as to allow estimating the values of the one or more structural parameters, characterizing the tested specimen, as described above and in more detail below.

As used herein, the term “target substance” is used to refer to a substance (i.e., material), which is included in a tested specimen and whose spectrum, at least about one characteristic X-ray line of the substance, is measured as part of measurement operation 110 (i.e., when method 100 is applied to the tested specimen).

It is noted that in embodiments wherein the one or more structural parameters are constituted by a single structural parameter, \vec{p}ₛ and the \vec{p}ₙ are one-dimensional vectors (i.e., scalars). Non-limiting examples include embodiments wherein only the thickness of a single layer, or the overall mass density of a single target substance, is to be determined.

According to some embodiments, and as expanded on below, for example, in the description of FIGS. 4A-4E, for each of the at least one target substance, and for each e-beam landing energy, in suboperation 110b, an X-ray emission spectrum in a photon energy range, which includes a characteristic X-ray line of the target substance, is measured. According to some embodiments, suboperation 110b may be implemented using an energy-dispersive X-ray (EDX) spectrometer and/or a wavelength-dispersive X-ray (WDX) spectrometer. According to some embodiments, and as elaborated on below in the description of suboperation 120a, in order to derive \vec{f}_{key}, onto each of the X-ray emission spectra a respective curve is fitted.

According to some embodiments, the photon energy range over which the X-ray emission spectra are measured may be narrow in the sense of being limited to a vicinity (e.g., about three times, about five times, or even about ten times the width) of a characteristic X-ray line, or an immediate vicinity of the characteristic X-ray line, of a target substance. Pertinent non-limiting examples include embodiments wherein a WDX spectrometer is used to obtain the measured spectra. Alternatively, according to some embodiments, and as described in more detail below, an X-ray detector and an optical filter may be employed to measure the intensity of the emitted X-rays at or about a characteristic X-ray line of a target substance.

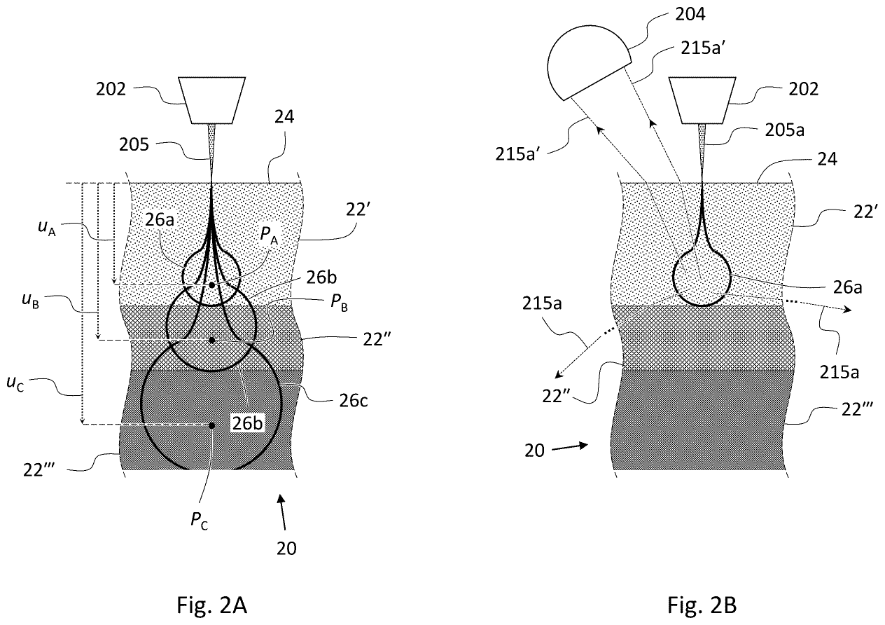

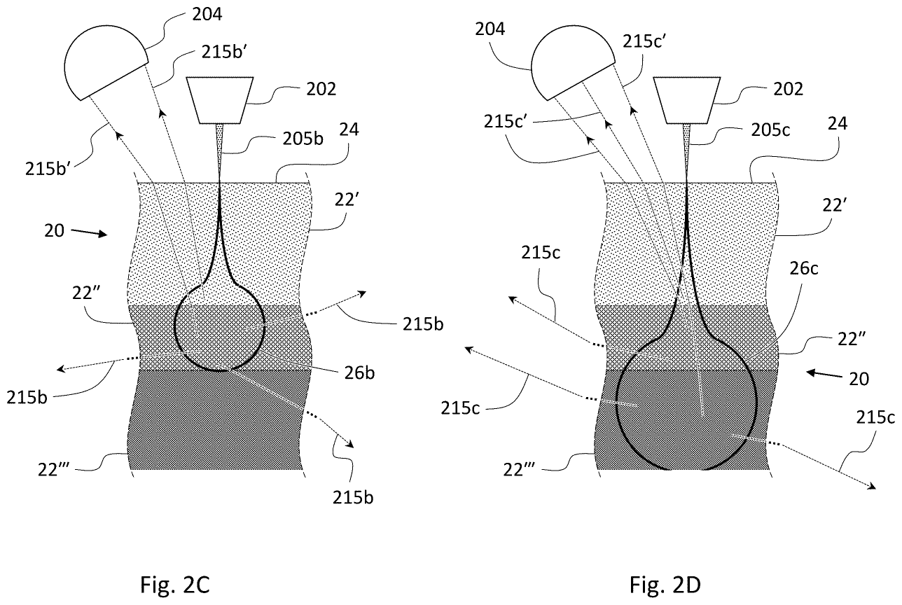

To facilitate the description, reference is additionally made to FIGS. 2A-2D. FIGS. 2A-2D schematically depict an implementation of measurement operation 110 of method 100, according to some embodiments thereof. FIG. 2A shows a cross-sectional view of a specimen 20 being probed by an e-beam in accordance with measurement operation 110. To render the description more concrete, it is assumed that specimen 20 includes a plurality of lateral (i.e., horizontal) layers 22 with at least some of layers 22 differing from one another in material composition (e.g., in the concentrations of one or more of the target substances). According to some embodiments, at least some of layers 22 may differ from one another in thickness.

As a non-limiting example, in FIGS. 2A-2D specimen 20 is shown as including three layers disposed one on top of the other: a first layer 22′, a second layer 22″, and a third layer 22′″. First layer 22′ is disposed above second layer 22″. Second layer 22″ is sandwiched between first layer 22′ and third layer 22′″. The top surface of first layer 22′ constitutes an external surface 24 of specimen 20. Also shown is an e-beam source 202 and an e-beam 205 produced thereby, so as to impinge (e.g., normally impinge) on external surface 24. E-beam source 202 may be configured to project e-beams (one at a time) at each of a plurality of e-beam landing energies, thereby implementing suboperation 110a.

The greater the landing energy of e-beam 205, the greater the depth to which electrons from e-beam 205 will (on average) penetrate into specimen 20. Further, the greater the landing energy of e-beam 205, the greater may be the volume within the specimen wherein electrons from e-beam 205 interact with matter in specimen 20 so as to induce emission of characteristic X-rays. This is exemplified in FIG. 2A via three probed regions 26: A first probed region 26a corresponds to the volume in which about all (e.g., at least 80%, at least 90%, or at least 95%) of the characteristic X-ray (i.e., electromagnetic X-ray radiation) emitting interactions will occur due to the penetration into specimen 20 of an e-beam at a first e-beam landing energy E₁. A second probed region 26b corresponds to the volume in which about all of the characteristic X-ray emitting interactions will occur due to the penetration into specimen 20 of an e-beam at a second e-beam landing energy E₂. A third probed region 26c corresponds to the volume in which about all of the characteristic X-ray emitting interactions will occur due to the penetration into specimen 20 of an e-beam at a third e-beam landing energy E₃. First probed region 26a is centered about a first point P₁ at a depth u₁, second probed region 26b is centered about a second point P₂ at a depth u₂, and third probed region 26c is centered about a third point P₃ at a depth u₃. E₁<E₂<E₃. Accordingly, u₁<u₂<u₃. According to some embodiments, and as depicted in FIG. 2A, third probed region 26c is of greater size than second probed region 26b, which is of greater size than first probed region 26a.

FIG. 2B shows a first e-beam 205a—generated by e-beam source 202 and having the first e-beam landing energy E₁—incident on specimen 20. Also delineated is first probed region 26a (in which about all the characteristic X-ray emitting interactions, induced by first e-beam 205a, occur). X-rays may be emitted in all directions, as exemplified by X-rays 215a. X-rays 215a′ indicate X-rays (from X-rays 215a), which arrive at an X-ray detector 204 (such as the X-ray detector of FIG. 5).

FIG. 2C shows a second e-beam 205b—generated by e-beam source 202 and having the second e-beam landing energy E₂—incident on specimen 20. Also delineated is second probed region 26b (in which about all the characteristic X-ray emitting interactions, induced by second e-beam 205b, occur). X-rays may be emitted in all directions, as indicated by X-rays 215b. X-rays 215b′ indicate X-rays (from X-rays 215b), which arrive at X-ray detector 204.

FIG. 2D shows a third e-beam 205c—generated by e-beam source 202 and having the third e-beam landing energy E₃—incident on specimen 20. Also delineated is third probed region 26c (in which about all the characteristic X-ray emitting interactions, induced by third e-beam 205c, occur). X-rays may be emitted in all directions, as indicated by X-rays 215c. X-rays 215c′ indicate X-rays (from emitted X-rays 215c), which arrive at X-ray detector 204.

While in FIGS. 2B-2D layers 22 are depicted as differing from one another in their respective refractive indices (as evinced by the refraction of the X-rays on transition from one layer to another), it is to be understood that method 100 is equally applicable without such differences being present.

For each of the e-beam landing energies (e.g. e-beam landing energies E₁, E₂, and E₃), respective measurement data of emitted X-rays may be obtained by X-ray detector 204, thereby implementing suboperation 110b. In particular, for each of the e-beam landing energy, the respective measurement data may include a respective X-ray emission spectrum (which X-ray detector 204 is configured to measure) in a photon energy range, which includes a least one characteristic X-ray line pertaining to a respective target substance of the at least one target substance. The intensity of a characteristic X-ray line corresponding to a target substance is indicative of the average concentration (i.e., particle density) of the target substance in the respective probed region. More specifically, each substance is characterized by a unique set of characteristic X-ray lines (i.e., spectral lines in the characteristic X-rays regime) corresponding to the energy differences between orbitals of elements making up the substance. The greater the concentration of a substance, the greater the measured intensity of each characteristic X-ray line pertaining thereto.

According to some embodiments, and as expanded on below in the description of FIG. 3, in suboperation 120b, the minimum distance between \vec{f}_{key} and a vector-valued function \vec{f}ₑₓₜ(\vec{p}) (extrapolated from the \vec{f}ₙ) may be computed, thereby obtaining \vec{p}ₛ. Each of the components of the vector-valued function quantifies the dependence of a respective (extrapolated) key feature on (the values of) the one or more structural parameters. The one or more structural parameters are parameterized by \vec{p}, wherein \vec{p} is a vector of free parameters (i.e., variables corresponding to the structural parameters, respectively). As detailed below, according to some embodiments, the minimum distance may be obtained by minimizing over \vec{p} with each of the components of \vec{p} being varied over a respective continuous range of values.

Alternatively, according to some embodiments, \vec{p}ₛ may obtained by applying a k-nearest neighbor (k-NN) regression algorithm (k<N) to \vec{f}_{key} with respect to the \vec{f}ₙ. According to some such embodiments, the \vec{p}ₙ include \vec{p}₀ (i.e., a vector specifying nominal values of the one or more structural parameters, or, put differently, corresponding to a simulated nominal specimen characterized by nominal values). Accordingly, the \vec{f}ₙ include a vector \vec{f}₀ obtained by the computer simulation when implemented with respect to a simulated specimen characterized by the nominal values (i.e., \vec{p}₀). It is noted that the k-NN regression algorithm may be weighted or non-weighted. That is, \vec{p}ₛ may be taken to equal the average or the weighted average of the \vec{p}ₙ corresponding to the k closest \vec{f}ₙ. Alternatively, \vec{p}ₛ may be taken to equal the median of the \vec{p}ₙ corresponding to the k \vec{f}ₙ closest to \vec{f}_{key}. Generally, i.e., when the one or more structural parameters include two or more structural parameters, the term “median” is to be understood as referring to a multi-variate extension of the (one-dimensional notion of the) median, such as the marginal median or the geometric median. More generally, \vec{p}ₛ may be substantially any function of the \vec{p}ₙ corresponding to the k \vec{f}ₙ closest to \vec{f}_{key}.

Still, according to some other embodiments, \vec{p}ₛ is determined as the output of a neural network. The neural network is configured to receive as input a vector of key features (i.e., \vec{f}_{key}) and to output \vec{p}ₛ. The neural network is trained using a training set including N pairs of vectors, such that, for each 1≤n≤N, \vec{f}ₙ serves as the (training) input and \vec{p}ₙ as the corresponding (training) output.

According to some embodiments, method 100 may further include an initial operation of deriving the \vec{f}ₙ (i.e., the set {\vec{f}ₙ}ₙ₌₁^{N}). For each 1≤n≤N, \vec{f}ₙ may be derived through computer simulation, which simulates for each landing energy: (i) the impinging of the respective simulated specimen, characterized by values \vec{p}ₙ of the one or structural parameters, by an e-beam (at the given landing energy), (ii) the penetration of the e-beam into the respective simulated specimen and the travel thereof therein, (iii) the resulting emission of X-rays from the respective simulated specimen, and, optionally, (iv) measurement of the emitted X-rays.

FIG. 3 presents a flowchart of a measurement data analysis operation 300, which corresponds to specific embodiments of measurement data analysis operation 120 of method 100. Measurement data analysis operation 300 includes:
A suboperation 310, wherein key features, specified by a vector \vec{f}_{key}, are extracted from the measurement data.
A suboperation 320, wherein \vec{p}ₛ is obtained as the (numerical or analytical) solution of minimization over a loss function depending on at least \vec{f}_{key} and \vec{f}ₑₓₜ(\vec{p}). (That is, \vec{p}ₛ minimizes the loss function.) \vec{f}ₑₓₜ(\vec{p}) is a vector-valued function of the key features obtained through extrapolation from {\vec{f}ₙ}ₙ₌₁^{N}.

Suboperations 310 and 320 correspond to specific embodiments of suboperations 120a and 120b, respectively, of method 100.

Each of the components of \vec{f}ₑₓₜ(\vec{p}) is a function quantifying the dependence—as prescribed by a model—of the corresponding key feature on the values \vec{p} of the one or more structural parameters. Thus, for example, fₑₓₜ^{(j)}(\vec{p}), the j-th component of \vec{f}ₑₓₜ(\vec{p}), is a function quantifying the dependence—per the model—of the j-th key feature (e.g., the j-th component of the energy signature) on \vec{p}.

According to some embodiments, in suboperation 320,

$${\vec{p}}_{s} = {arg min D}_{\vec{p}} ( {\vec{f}}_{key} , {\vec{f}}_{ext} ( \vec{p} ) ) .$$

D(\vec{v}₁, \vec{v}₂) denotes a mathematical distance (which may or not be a norm) between a pair of vectors \vec{v}₁ and \vec{v}₂ (so that D (\vec{f}_{key}, \vec{f}ₑₓₜ(\vec{p})) is a (mathematical) distance between \vec{f}_{key} and \vec{f}ₑₓₜ(\vec{p})). Non-limiting examples of distances include the L¹ norm and the L² norm. (It is noted that in embodiments wherein the norm is L², and \vec{f}ₑₓₜ(\vec{p}) is linear in \vec{p}, the optimization problem admits an analytical solution.) According to some such embodiments,

$${\vec{p}}_{s} = {arg min}_{\vec{p}} ‖ {\vec{f}}_{key} - {\vec{f}}_{ext} ( \vec{p} ) ‖ .$$

The double vertical bars denote a vector norm (e.g. a Euclidian norm: ∥\vec{f}_{key}−\vec{f}ₑₓₜ(\vec{p})∥₂={square root over ((f_{key}−\vec{f}ₑₓₜ(\vec{p}))²)}). More generally, and as elaborated on below, \vec{p}ₛ may be determined via

$${\vec{p}}_{s} = {arg min}_{\vec{p}} ( {min}_{{M}_{1} , {M}_{2}} D ( {M}_{1} {\vec{f}}_{key} , {M}_{2} {\vec{f}}_{ext} ( \vec{p} ) ) ) ,$$

wherein M₁ and M₂ are matrices having suitably selected properties as specified below. In particular, each of M₁ and M₂ may be a positive definite matrix—optionally, diagonal—with a respective minimum eigenvalue which is greater than a respective prespecified (positive) threshold.
According to some embodiments, a regularizing term(s) may be added to the norm ∥\vec{f}_{key}−\vec{f}ₑₓₜ(\vec{p})∥ (or, more generally, ∥M₁\vec{f}_{key}−M₂\vec{f}ₑₓₜ(\vec{p})∥, D (M₁\vec{f}_{key}, M₂\vec{f}ₑₓₜ(\vec{p})), or a first term—depending on \vec{f}_{key} and \vec{f}ₑₓₜ(\vec{p}) —of a loss function) to stabilize the solution or as a constraint(s), which reflects some prior knowledge about the one or more structural parameters.

According to some embodiments, the extrapolation is to a linear function. That is, \vec{f}ₑₓₜ(\vec{p})=\vec{f}ₑₓₜ(\vec{p}₀+\vec{δ})=\vec{f}₀+A\vec{δ}=\vec{f}₀+A(\vec{p}−\vec{p}₀), wherein \vec{f}₀ is a vector of values of the key features corresponding to \vec{p}₀. A is a K_{f}×Kₚ matrix. K_{f} is the number of key features, i.e., the dimensionality of \vec{f}ₑₓₜ(\vec{p}₀+\vec{δ}) (and of \vec{f}₀ and each of the \vec{f}ₙ). Kₚ is the dimensionality of \vec{p}₀ (and the \vec{p}ₙ), that is, the number of the one or more structural parameters of the tested specimen (and each of the simulated specimens), which are to be determined. \vec{f}₀ specifies the values of the key features corresponding to a nominal specimen (i.e., characterized by the nominal values \vec{p}₀).

According to some embodiments, \vec{f}₀ may be obtained in the same way as the \vec{f}ₙ are obtained. That is, through a computer simulation simulating the striking and penetration into a specimen, characterized by \vec{p}₀, of e-beams at each of the at least one landing energy, and the consequent emission of X-rays. According to some such embodiments,

$$A = {arg min}_{B} ‖ ( \begin{matrix}{( {\vec{f}}_{1} - {\vec{f}}_{0} - B {\vec{δ}}_{1} )}^{T} \\ {( {\vec{f}}_{2} - {\vec{f}}_{0} - B {\vec{δ}}_{2} )}^{T} \\ ⋮ \\ {( {\vec{f}}_{N} - {\vec{f}}_{0} - B {\vec{δ}}_{N} )}^{T}\end{matrix} ) ‖ .$$

For each 1≤n≤N, \vec{δ}ₙ=\vec{p}ₙ−\vec{p}₀. B is a K_{f}×Kₚ matrix. The double vertical bars denote a matrix norm (e.g. the Frobenius norm). Optionally, according to some embodiments, a regularizing term(s) may be added to the matrix norm, in which case the minimization is to be understood as being over the sum of the matrix norm and the regularizing term(s).

Alternatively, according to some embodiments, similarly to the matrix A, \vec{f}₀ is determined through optimization. In particular, according to some such embodiments, both \vec{f}₀ and the matrix A are obtained as the solution of

$${arg min}_{\vec{g} , B} ‖ ( \begin{matrix}{( {\vec{f}}_{1} - \vec{g} - B {\vec{δ}}_{1} )}^{T} \\ {( {\vec{f}}_{2} - \vec{g} - B {\vec{δ}}_{2} )}^{T} \\ ⋮ \\ {( {\vec{f}}_{N} - \vec{g} - B {\vec{δ}}_{N} )}^{T}\end{matrix} ) ‖$$

with the double vertical bars denoting a matrix norm (e.g. the Frobenius norm). Optionally, according to some embodiments, a regularizing term(s) may be added to the matrix norm, in which case the minimization is to be understood as being over the sum of the matrix norm and the regularizing term(s).

According to some embodiments, the extrapolation may be to a non-linear function of \vec{δ}. As a non-limiting example, according to some such embodiments, \vec{f}ₑₓₜ(\vec{p}₀+\vec{δ}) is a square function of \vec{δ}. That is, in such embodiments, for each 1≤c≤K_{f}, the c-th component of \vec{f}ₑₓₜ(\vec{p}₀+\vec{δ}) will include (in addition to a linear contribution and a constant) a square contribution given by Σ_{b=1}^{K}^{ₚ} Σₐ₌₁^{K}^{ₚ} T_{ab}^{(c)}δₐδ_{b}, wherein T_{ab}^{(c)} denotes the (a, b)-th component of a Kₚ×Kₚ matrix T^{(c)}.

Optimization problems specified throughout the application may be solved using standard local and/or global optimization algorithms, such as gradient descent or quasi-Newton. According to some embodiments, wherein a specified optimization problem admits a known analytical solution, the quantity (e.g., \vec{p}ₛ, the matrix A, \vec{f}₀) sought to be optimized may be computed directly from the (function defining the) analytical solution. As a non-limiting example, in embodiments wherein \vec{f}ₑₓₜ(\vec{p}) is linear in \vec{p} (that is, \vec{f}ₑₓₜ(\vec{p})=Ã\vec{p}+\vec{b} with Ã being a matrix) and the norm is L², the optimization problem assumes the form

$${arg min}_{\vec{p}} ‖ Ã \vec{p} + \vec{b} - {\vec{f}}_{key} ‖ ,$$

so that \vec{p}ₛ=\tilde{M}(\vec{f}_{key}−\vec{b}), wherein the matrix \tilde{M} is Moore-Penrose inverse of Ã. As yet another example, in embodiments wherein

$${arg min}_{B} ‖ ( \begin{matrix}{( {\vec{f}}_{1} - {\vec{f}}_{0} - B {\vec{δ}}_{1} )}^{T} \\ {( {\vec{f}}_{2} - {\vec{f}}_{0} - B {\vec{δ}}_{2} )}^{T} \\ ⋮ \\ {( {\vec{f}}_{N} - {\vec{f}}_{0} - B {\vec{δ}}_{N} )}^{T}\end{matrix} ) ‖$$

admits a (known) analytical solution, as is the case, for instance, when the matrix norm is the Frobenius norm, A may be obtained by plugging the \vec{f}ₙ and the \vec{δ}ₙ into the (function defining the) analytical solution. More precisely, the analytical solution is given by A=(F−F₀)Q, wherein Q is the Moore-Penrose inverse of a matrix \tilde{D} whose columns are constituted by the \vec{δ}ₙ, F is a matrix whose columns are constituted by the \vec{f}ₙ, and F₀ is matrix whose columns are each constituted by \vec{f}₀. Finally, in embodiments wherein

$${arg min}_{\vec{g} , B} ‖ ( \begin{matrix}{( {{f}_{1}}^{→︀} - {g}^{→︀} - B {\vec{δ}}_{1} )}^{T} \\ {( {{f}_{2}}^{→︀} - {g}^{→︀} - B {\vec{δ}}_{2} )}^{T} \\ ⋮ \\ {( {{f}_{N}}^{→︀} - {g}^{→︀} - B {\vec{δ}}_{N} )}^{T}\end{matrix} ) ‖$$

admits a (known) analytical solution, as is the case, for example, when the matrix norm is the Frobenius norm, \vec{f}₀ and A may be obtained by plugging the \vec{f}ₙ and the \vec{δ}ₙ into the (function defining the) analytical solution. Through suitable manipulation, the analytical solution may be obtained in essentially the same manner as in the case wherein only A is to be determined (i.e., when \vec{f}₀ is given).

Optionally, according to some embodiments, measurement data analysis operation 300 may further include, prior to suboperation 320, an (optional) suboperation (not specified in FIG. 3) of obtaining {\vec{f}ₙ}ₙ₌₁^{N} by subjecting \vec{f}_{key} to an (k=N)−NN classifier with respect to a set of N′>N vectors of key features {\vec{f}ᵢ}ᵢ₌₁^{N′}, which includes the \vec{f}ₙ (optionally, relabeled). The additional N′−N vectors (i.e., beyond {\vec{f}ₙ}ₙ₌₁^{N}) are obtained by applying the computer simulation with respect to N′−N additional simulated specimens. The full set of N′ \vec{p}ᵢ may be selected as described above in the description of method 100.

Referring again to method 100, according to some embodiments, in suboperation 120a (and therefore also suboperation 310), in order to derive \vec{f}_{key}, onto each of the X-ray emission spectra (obtained for each of the e-beams projected in measurement operation 110) a respective curve is fitted. This is illustrated by way of example in FIGS. 4A-4E, according to some embodiments, in the case wherein \vec{f}_{key} is given by the energy signature associated with a single target substance and a single spectral line (i.e., single characteristic X-ray line). A more general case, wherein the energy signature is associated with a plurality of target substances, and/or for at least some of the target substances a plurality of spectral lines thereof is taken into account, is described later on.

Referring to FIG. 4A, FIG. 4A depicts a measured (X-ray emission) spectrum 400, which was obtained by implementing measurement operation 110 with respect to a tested specimen (e.g., specimen 20). As is also the case in each of FIGS. 4B-4E, the horizontal axis corresponds to the photon energy ε (or equivalently the frequency) of the emitted X-rays and the vertical axis to the intensity I of the emitted X-rays. The graduations on each of the horizontal and vertical axes are linearly spaced-apart with εᵢ<εᵢ₊₁ and Iᵢ<Iᵢ₊₁. A peak 410 of measured spectrum 400 is substantially centered about a characteristic X-ray line of a target substance, which is included in the tested specimen, and whose energy signature is to be obtained. FIG. 4B depicts an optimized curve 450, which was fitted onto measured spectrum 400. FIG. 4C depicts optimized curve 450 superimposed on measured spectrum 400.

According to some embodiments, the fitting onto measured spectrum 400 involves optimizing over values of one or more adjustable parameters of a curve (also referred to as the “free curve”), thereby obtaining optimized curve 450. The values of the one or more adjustable parameters are fixed by minimizing (over the one or more adjustable parameters) a distance between the free curve and the measured spectrum.

The one or more adjustable parameters may include a (first) adjustable parameter whose value is indicative of an intensity of the emitted X-rays about the characteristic X-ray line of the target substance. According to some such embodiments, the adjustable parameter is a multiplicative coefficient of a normalized cap-shaped function (e.g., a normalized gaussian), which may be centered the characteristic X-ray line. According to some embodiments, the one or more adjustable parameters include a plurality of adjustable parameters, which may include—in addition to the first adjustable parameter—an additive bias parameter, at least one parameter governing a shape of the cap-shaped function (e.g., the width of a normalized gaussian), and/or a (characteristic X-ray) line shift parameter governing the location of the center of the cap-shaped function.

More generally, according to some embodiments, the free curve may be a sum of at least two adjustable functions: an adjustable cap-shaped function, which may be centered about the characteristic X-ray line, and an adjustable second function quantifying the (continuous) spectrum of the bremsstrahlung (i.e., background radiation) component of the respective measured X-ray emission spectrum (e.g. the background radiation in the vicinity of the characteristic X-ray line). As a non-limiting example, the at least one landing energy includes N_{E} e-beam landing energies {Eᵢ}ᵢ₌₁^{N}^{_{E}}, so that N_{E} X-ray emission spectra are measured: {sᵢ(ε)}ᵢ₌₁^{N}^{_{E}}. Here ε denotes a photon energy of the emitted X-rays and sᵢ(ε) —the i-th measured X-ray emission spectrum—is the measured X-ray emission spectrum induced by projecting an e-beam at the landing energy Eᵢ. According to some embodiments, a set of N_{E} free curves {cᵢ(ε)}ᵢ₌₁^{N}^{_{E}} may be fitted onto the set of measured spectra {sᵢ(ε)}ᵢ₌₁^{N}^{_{E}}. According to some embodiments, for each 1≤i≤N_{E}, cᵢ(ε)=Gᵢ(ε)+bᵢ(ε), wherein Gᵢ(ε) is the adjustable cap-shaped function and bᵢ(ε) is the adjustable second function. Gᵢ(ε)=aᵢ·gᵢ(ε), wherein gᵢ(ε) is a normalized cap-shaped function and aᵢ is a multiplicative coefficient. According to some embodiments, gᵢ(ε) may be a (normalized) gaussian, in which case the width and, optionally, center of gᵢ(ε) may be adjustable parameters (over which the optimization is carried out). According to some alternative embodiments, gᵢ(ε) may be a (normalized) gamma distribution or generalized gaussian distribution. According to some embodiments, bᵢ(ε) may be a polynomial (e.g., a first order polynomial or a second order polynomial) whose coefficients are adjustable. Alternatively, according to some embodiments, bᵢ(ε) may be determined from Kramer's law.

Since gᵢ(ε) is normalized, aᵢ substantially equals the intensity of the X-rays (or equivalently the number of photons) emitted due to transitions—which correspond to the characteristic X-ray line of the target substance—a and collected (detected) by the X-ray measurement module.

Denoting by {g_{i, j}}ⱼ₌₁^{j}^{ₘₐₓ} and {b_{i, k}}ₖ₌₀^{k}^{ₘₐₓ} the adjustable parameters of gᵢ(ε) and bᵢ(ε), respectively, for each 1≤i≤N_{E}, the optimized values âᵢ, {ĝ_{i, j}}ⱼ₌₁^{j}^{ₘₐₓ} and {\hat{b}_{i, k}}ⱼ₌₁^{j}^{ₘₐₓ} of the adjustable parameters may be obtained by minimizing D(cᵢ(ε), sᵢ(ε)) over aᵢ, {g_{i, j}}ⱼ₌₁^{j}^{ₘₐₓ}, and {b_{i, k}}ₖ₌₀^{k}^{ₘₐₓ}. D(cᵢ(ε), sᵢ(ε)) is a distance between cᵢ(ε) and sᵢ(ε). More generally, according to some embodiments, the optimized values may be obtained by minimizing over a loss function depending at least on cᵢ(ε) and sᵢ(ε). As a non-limiting example, according to some embodiments, wherein gᵢ(ε) is gaussian and bᵢ(ε) is a second order polynomial: (i) {g_{i, j}}ⱼ₌₁²={g_{i, 1}, g_{i, 2}} with g_{i, 1} and g_{i, 2} parameterizing the width and center of the gaussian; and (ii) {b_{i, k}}ₖ₌₀²={b_{i, 0}, b_{i, 1}, b_{i, 2}} with b_{i, 0}, b_{i, 1}, and b_{i, 2} being the zeroth order, first order, and second order coefficients of the polynomial. In particular, âᵢ=argmin aᵢ min_{{g}_{ᵢ}_{, j}}ⱼ₌₁^{j}^{ₘₐₓ}_{, {b}_{_{i, k}}_{}}_{ₖ₌₁}^{k}^{ₘₐₓ}D (cᵢ(ε), sᵢ(ε)). According to some embodiments, D(cᵢ(ε), sᵢ(ε))=∫dε|cᵢ(ε)−sᵢ(ε)|² (or a discretized equivalent expression). According to some embodiments, a regularization term may be added to D(cᵢ(ε), sᵢ(ε)) to take into account prior knowledge regarding any of the free parameters and/or stabilize the solution (of the minimization algorithm).

According to some alternative embodiments, wherein there exists prior knowledge relating at least some of the free parameters to one another, the full set of optimized values, i.e., {âᵢ, {ĝ_{i, j}}ⱼ₌₁^{j}^{ₘₐₓ}, {\hat{b}_{i, k}}ₖ₌₀^{k}^{ₘₐₓ}}ᵢ₌₁^{N}^{_{E}} (or equivalently {âᵢ, ĝᵢ(ε), \hat{b}ᵢ(ε)}ᵢ₌₁^{N}^{_{E}}, wherein ĝᵢ(ε) and \hat{b}ᵢ(ε) denote the optimized functions defined by {ĝ_{i, j}}ⱼ₌₁^{j}^{ₘₐₓ} and {\hat{b}_{i, k}}ₖ₌₀^{k}^{ₘₐₓ}, respectively) is obtained by jointly optimizing over all of the adjustable parameters, i.e., {aᵢ, {g_{i, j}}ⱼ₌₁^{j}^{ₘₐₓ}, {b_{i, k}}ₖ₌₀^{k}^{ₘₐₓ}}ᵢ₌₁^{N}^{_{E}} subject to constraints imposed by the aforementioned prior knowledge. More specifically, in such embodiments,

$$\begin{matrix}\begin{matrix}{\{ {\hat{a}}_{i} \}}_{i = 1}^{{N}_{E}} = arg {min}_{{\{ {a}_{i} \}}_{i = 1}^{{N}_{E}}} {min}_{{\{ {\{ {g}_{i} , j \}}_{j = 1}^{{j}_{max}} , {\{ {b}_{i} , k \}}_{k = 0}^{{k}_{max}} \}}_{i = 0}^{{N}_{E}}} {\sum }_{i = 1}^{{N}_{E}} D ( {c}_{i} ( ε ) , {s}_{i} ( ε ) ) \\ \end{matrix} \\ {\begin{matrix}s . t . & \{ {Q}_{l} \}\end{matrix}}_{l = 1}^{{N}_{c}} ,\end{matrix}$$

wherein {Qₗ}ₗ₌₁^{N}^{_{c}} is a set of N_{c} constraints. (That is, each of the Qₗ is an equation, or inequality, relating at least some of the free parameters to one another.)

As a non-limiting example, according to some embodiments depicted in FIGS. 4B-4E, the free curve is a sum of three adjustable functions. In addition to gᵢ(ε), which is gaussian, and bᵢ(ε), which is a second order polynomial, the sum additionally includes a gaussian Yᵢ(ε). Referring to FIG. 4D, a curved line 460 corresponds to âᵢ·ĝᵢ(ε)+Ŷᵢ(ε). Ŷᵢ(ε) (which is also gaussian) was obtained by optimizing over free parameters of Yᵢ(ε). ĝᵢ(ε) is centered about the characteristic X-ray line of the target substance. Ŷᵢ(ε) is centered about a characteristic X-ray line of a (non-target) second substance present in the tested specimen. The characteristic line of the second substance is close to the characteristic line of the target substance and accordingly was taken into account in order to improve the accuracy of the determination of \vec{f}_{key} (and consequently \vec{p}ₛ). Referring to FIG. 4E, a curved line 470 corresponds to \hat{b}ᵢ(ε). Curved line 470 is also plotted in FIG. 4C.

According to some embodiments, wherein the X-ray emission spectrum about a single characteristic X-ray line of a single target substance (included in the tested specimen) is used to determine \hat{f}_{key}, the number of components of \vec{f}_{key} is equal to the number of e-beam landing energies. According to some embodiments, for each 1≤j≤J, for f_{key}^{(j)} is equal to âⱼ—the j-th component of the energy signature. More generally, according to some embodiments, for each 1≤j≤J, f_{key}^{(j)}=f_{key} (âⱼ, {\hat{b}_{j, k}}ₖ₌₀^{k}^{ₘₐₓ}), wherein f_{key} (âⱼ, {\hat{b}_{j, k}}ₖ₌₀^{k}^{ₘₐₓ}) is a function of âⱼ and {b_{j, k}}ₖ₌₀^{k}^{ₘₐₓ}. That is, for each 1≤j≤J, the j-th component of the energy signature is a function of both âⱼ and the coefficients of \hat{b}ⱼ(ε). According to some such embodiments, f_{key} (âⱼ, {\hat{b}_{j, k}}ₖ₌₀^{k}^{ₘₐₓ})=f_{key} (âⱼ, q ({\hat{b}_{j, k}}ₖ₌₀^{k}^{ₘₐₓ}) wherein q is a function of the coefficients of \hat{b}ⱼ(ε). As a non-limiting example, according to some embodiments, q ({\hat{b}_{j, k}}ₖ₌₀^{k}^{ₘₐₓ})=(\hat{b}ⱼ(ε)) and f_{key} (âⱼ, q ({\hat{b}_{j, k}}ₖ₌₀^{k}^{ₘₐₓ})=âⱼ/(bⱼ(ε)), wherein the triangular brackets denote averaging about the center of ĝⱼ(ε) along an interval equal to the width of ĝⱼ(ε).

According to some embodiments, the key features may be derived based on a dependence on the e-beam landing energy of the intensities of the emitted X-rays about each of a plurality of different characteristic X-ray lines. According to some such embodiments, wherein N_{L} is the number of different characteristic X-ray lines, the key features are specified by a J=N_{E}×N_{L} component vector with components f_{key}⁽ⁿ^{_{E}}^{,n}^{_{L}}⁾ with 1≤n_{E}≤N_{E} and 1≤n_{L}≤N_{L} (N_{E} is the number of landing energies). The first index denotes the e-beam landing energy and the second index denotes the characteristic X-ray line. That is, \vec{f}_{key}=(f_{key}^{(1,1)}, f_{key}^{(1,2)}, . . . , f_{key}^{(1,N}^{_{L}}⁾, f_{key}^{(2,1)}, f_{key}^{(2,2)}, . . . , f_{key}^{(2,N}^{_{L}}⁾, . . . , f_{key}^{(N}^{_{E}}^{,1)}, f_{key}^{(N}^{_{E}}^{,2)}, . . . , f_{key}^{(N}^{_{E}}^{,N}^{_{L}}⁾). In such embodiments, in measurement operation 110, for each e-beam landing energy, the X-ray emission spectrum is measured over a photon energy range or photon energy ranges including the plurality of characteristic X-ray lines. The components of \vec{f}_{key} pertaining to a same characteristic X-ray line (e.g. f_{key}^{(1,2)}, f_{key}^{(2,2)}, . . . , f_{key}^{(N}^{_{E}}^{,2)}) may be obtained as described above in the case wherein N_{L}=1. According to some embodiments, wherein the at least one target substance includes N_{sub} (N_{sub}≤N_{L}) target substances, the N_{L} characteristic X-ray lines include characteristic X-ray lines corresponding to each of the N_{sub} target substances, respectively.

As mentioned above, according to some embodiments,

$${{p}^{→︀}}_{s} = {arg min}_{{p}^{→︀}} ( {min}_{{M}_{1} , {M}_{2}} D ( {M}_{1} {{f}^{→︀}}_{key} , {M}_{2} {{f}^{→︀}}_{ext} ( {p}^{→︀} ) ) ) ,$$

M₁ and M₂ are matrices having suitably selected properties (e.g. positive-definiteness and symmetries as specified below) and D (M₁\vec{f}_{key}, M₂\vec{f}ₑₓₜ(\vec{p}) denotes a mathematical distance between M₁\vec{f}_{key} and M₂\vec{f}ₑₓₜ(\vec{p}). According to some embodiments, one or more regularizing terms may be added to

$${min}_{{M}_{1} , {M}_{2}} D ( {M}_{1} {{f}^{→︀}}_{key} , {M}_{2} {{f}^{→︀}}_{ext} ( {p}^{→︀} ) ) .$$

To render the description more concrete by way of a non-limiting example, addressed in detail are embodiments wherein the X-ray emission spectrum about a single characteristic X-ray line of a single target substance is used to determine \hat{f}_{key}, such that for each 1≤j≤N_{E}, f_{key}^{(j)} is equal to âⱼ and f_{key}^{(N}^{_{E}}^{+j)}= [symbol] \hat{b}ⱼ(ε) [symbol] (i.e., the number of components of \hat{f}_{key} is equal to 2N_{E}). That is, the first N_{E} components of \vec{f}_{key} are unnormalized energy signature components and the last N_{E} components are pure bremsstrahlung (i.e., background radiation) components. According to some such embodiments,

$${{p}^{→︀}}_{s} = {arg min}_{{p}^{→︀}} ( {min}_{M} D ( {{f}^{→︀}}_{key} , M {{f}^{→︀}}_{ext} ( {p}^{→︀} ) ) )$$

(so that M₁ equals the identity matrix and M₂=M). M is a diagonal matrix whose diagonal terms are pairwise equal in the sense that for each 1≤j≤N_{E} M_{N}_{_{E}}_{+j, N}_{_{E}}₊ⱼ=M_{j,j}≥T, wherein T is a the prespecified (positive) threshold. That is, for each 1≤j≤N_{E}, the (N_{E}+j)-th component along the diagonal of M equals the j-th component there along. Accordingly, for each 1≤j≤N_{E}, âⱼ and (\hat{b}ⱼ(ε)) are weighted by the same respective factor. The inclusion of M, and the minimization thereover, may account for potentially different scaling of components \vec{f}ₑₓₜ(\vec{p}) and corresponding components of \vec{f}_{key}, whereby, for at least some 1≤j≤N_{E}, a scale of \vec{f}ₑₓₜ^{(j)}(\vec{p}) and fₑₓₜ^{(N}^{_{E}}^{+j)}(\vec{p}) varies from that of f_{key}^{(j)} and f_{key}^{(N}^{_{E}}^{+j)}. According to some such embodiments,

$${{p}^{→︀}}_{s} = {arg min}_{{p}^{→︀}} ( {min}_{M} ‖ {{f}^{→︀}}_{key} - M {{f}^{→︀}}_{ext} ( {p}^{→︀} ) ‖ ) .$$

According to some embodiments, one or more regularizing terms may be added to

$${min}_{M} ‖ {{f}^{→︀}}_{key} - M {{f}^{→︀}}_{ext} ( {p}^{→︀} ) ‖ .$$

More generally, according to some embodiments,

$${{p}^{→︀}}_{s} = {arg min}_{{p}^{→︀}} ( {F}_{0} ( {{f}^{→︀}}_{key} , {{f}^{→︀}}_{ext} ( {p}^{→︀} ) ) ) ,$$

wherein F₀ (\vec{f}_{key}, \vec{f}ₑₓₜ(\vec{p})) is a loss function, which depends on \vec{f}_{key} and \vec{f}ₑₓₜ(\vec{p}) and is equal to

$${min}_{M} {\tilde{F}}_{0} ( {{f}^{→︀}}_{key} , M {{f}^{→︀}}_{ext} ( {p}^{→︀} ) )$$

(with M having the above specified properties and symmetries, i.e., pairwise equality). \tilde{F}₀ (\vec{f}_{key}, M \vec{f}ₑₓₜ(\vec{p})) is a function (e.g., a loss function) depending on \vec{f}_{key} and M \vec{f}ₑₓₜ(\vec{p}). According to some embodiments,

$${{p}^{→︀}}_{s} = {arg min}_{{p}^{→︀}} ( {min}_{M} {\tilde{F}}_{0} ( {{f}^{→︀}}_{key} , M {{f}^{→︀}}_{ext} ( {p}^{→︀} ) ) + {F}_{1} ( {p}^{→︀} ) ) ,$$

wherein F₁(\vec{p}) is a regularizing function including one or more regularizing terms.

According to some embodiments, wherein a spectrometer is used to obtain the X-ray emission spectra, measurement data analysis operation 120 may include an initial preprocessing suboperation, wherein the X-ray emission spectra may be preprocessed to remove noise.

According to some embodiments of method 100, suboperation 120a includes an initial suboperation wherein difference spectra are obtained by subtracting measured (control) spectra of a control specimen from the measured spectra, respectively, of the tested specimen, which are obtained in measurement operation 110. The control spectra may be of a gold standard specimen, which is known, or assumed, to closely match the intended design of the tested specimen in the sense that one or more structural parameters (optionally, also structural parameters which are not estimated by method 100) of the gold standard specimen do not deviate by more than 1%, 2%, or 5% from the nominal values thereof. Each possibility corresponds to separate embodiments.

More specifically, the difference spectra may be processed (in suboperation 120a) to extract therefrom a vector of key features \vec{f}_{dif}, essentially as described above in the description of FIGS. 4A-4E with the difference that (due to the subtraction) any accounting for bremsstrahlung is obviated. In such embodiments, the computer simulation of suboperation 120b is configured to receive as an input \vec{f}_{dif}, and output \vec{p}ₛ, based on a set of N vectors of simulated key features {\vec{f}′ₙ}ₙ₌₁^{N}. For each 1≤n≤N, \vec{f′}ₙ may be taken to equal \vec{f}ₙ−\vec{f}₀. \vec{f}′ₙ is obtained using the computer simulation when implemented with respect to the n-th simulated specimen (i.e., the simulated specimen characterized by \vec{p}ₙ). \vec{f}₀ is obtained using the control specimen when implemented with respect to the control specimen, which for the purposes of the computer simulation is assumed to be exactly characterized by \vec{p}₀. It is noted that in embodiments including extrapolation, the zeroth order term in \vec{δ}=\vec{p}−\vec{p}₀ will be zero. Accordingly, when the extrapolation is onto a linear function, the extrapolated function will have the form A\vec{δ}.

According to some such embodiments, method 100 may additionally include obtaining the control spectra, e.g., by implementing measurement operation 110 with respect to the control specimen.

It is to be understood that the applicability of method 100 is not limited to specimens including nominally flat layers (as depicted by way of a non-limiting example in FIGS. 2A-2D), and, more generally, layered specimens. Regions differing from one another in material composition may in principle be arbitrarily shaped. In particular, method 100 may be applied to structures including localized embedded (buried) features, such as nanowires, gate-all-around nanosheets, and, more generally, channels. Method 100 may also be applied to specimens characterized by continuously varying densities of substances included therein as function of the depth coordinate and/or, in the three-dimensional case, as a function of the lateral coordinates. Further, the skilled person will readily perceive that method 100 may be applied to specimens including empty cavities and/or holes.

### Systems

According to an aspect of some embodiments, there is provided a computerized system for non-destructive three-dimensional probing and characterization of specimens (such as semiconductor structures, e.g., included in patterned wafers) based on X-ray measurements and subsequent analysis of the obtained measurement data using a computer simulation. FIG. 5 schematically depicts such a system, a computerized system 500, according to some embodiments. As will be apparent from the description of system 500, system 500 may be used to implement method 100 (including specific embodiments of method 100, which include measurement data analysis operation 300). In particular, system 500 may be used to determine values of one or more structural parameters characterizing a tested specimen. Non-limiting examples of structural parameters, which may be estimated using system 500, are listed above in the Methods Subsection in the description of method 100.

System 500 includes an e-beam source 502, an X-ray detector 504 (or, more generally, an X-ray sensing assembly including two or more X-ray detectors), a processing circuitry 506, and a controller 508. According to some embodiments, system 500 may further include a stage 520 (e.g., a xyz stage) configured to accommodate a (tested) specimen 50. According to some embodiments, e-beam source 502, X-ray detector 504, and controller 508 form part of a scanning electron microscope. According to some embodiments, specimen 50 may be a patterned wafer or a structure (e.g., a semiconductor structure) included in or on a patterned wafer. According to some such embodiments, specimen 50 may be a preliminary structure in one of the fabrication stages of a patterned wafer or an assist structure employed in one of the fabrication stages of a patterned wafer. According to some embodiments, specimen 50 may be or include one or more memory components and/or logic components (such as a gate stack, for example, a high-k metal gate stack). It is noted that specimen 50 does not form part of system 500.

Dotted lines between elements indicate functional or communicational association there between.

E-beam source 502 is configured to produce e-beams at a plurality of e-beam landing energies. In particular, e-beam source 502 is configured to produce e-beams at each of a plurality of landing energies, so as to allow probing specimen 50 to a plurality of depths, respectively, essentially as described above in the description of suboperation 110a of method 100.

The greater the depth to which a tested specimen is to be probed, the greater the maximum e-beam landing energy, and, optionally, the number of e-beam landing energies. According to some embodiments, the plurality of e-beam landing energies may include landing energies up to about 5 keV, about 10 keV, about 15 keV, about 20 keV, or even about 30 keV. Each possibility corresponds to different embodiments. In silicon, an e-beam with a landing energy of about 15 keV may penetrate as deep as about 3 μm.

The durations of the projections of the e-beams may be dictated by the required precision to which \vec{p}ₛ (i.e., the values of the one or more structural parameters characterizing specimen 50) is to be determined.

An e-beam 505, generated by e-beam source 502, is shown incident on (an external surface 54 of) specimen 50, according to some embodiments. As a result of the impinging of e-beam 505 on specimen 50, and the penetration of e-beam 505 into specimen 50, X-rays, and, in particular, characteristic X-rays, are generated. A portion of these X-rays, constituted by X-rays 515, arrives at X-ray detector 504.

According to some embodiments, X-ray detector 504 is sensitive to electromagnetic radiation in the X-ray photon energy range (at least over the characteristic X-rays regime or one or more subranges thereof). According to some embodiments, X-ray detector 504 may be an EDX spectrometer or a WDX spectrometer. According to some embodiments, instead of a single X-ray detector, an X-ray detector assembly, which includes both an EDX spectrometer and a WDX spectrometer, may be used. In such embodiments the X-ray emission spectra may be obtained using both an EDX spectrometer and a WDX spectrometer with the WDX spectrometer being used to “zoom in” on the characteristic X-ray lines. In particular, the greater resolution of the WDX spectrometer (which renders it slower), as compared to the EDX spectrometer, allows obtaining narrower peaks and dips. According to some embodiments, wherein the spectrometer is a WDX spectrometer, X-ray detector 504 may be configured to allow scanning over extended photon energy ranges (thereby allowing to obtain X-ray emission spectra over extended photon energy ranges). X-ray detector 504 is configured to relay (optionally, via controller 508) the measurement data collected thereby (e.g., the spectrum of X-rays incident thereon) to processing circuitry 506.

According to some embodiments, system 500 may additionally include a window (not shown) positioned between X-ray detector 504 and stage 520, which may be configured to controllably and differentially attenuate the spectrum of the emitted X-rays and/or protect an X-ray sensitive surface of the spectrometer.

According to some alternative embodiments, X-ray detector 504 is configured to measure the intensity of electromagnetic X-ray radiation (i.e., electromagnetic radiation in the X-ray photon energy range) at or about a characteristic X-ray line of a (target) substance included in specimen 50 without additionally measuring the intensity of the electromagnetic X-ray radiation over an extended photon energy range outside the immediate vicinity of the characteristic X-ray line. According to some such embodiments, system 500 may additionally include an optical filter (not shown). The optical filter is configured to block electromagnetic radiation having a photon energy outside the immediate vicinity of the characteristic X-ray line from reaching X-ray detector 504.

According to some embodiments, system 500 may include additional elements. The additional elements may include electron optics (not shown; e.g., an electrostatic lens(es) and a magnetic deflector(s)), which may be used to guide and manipulate an e-beam generated by e-beam source 502. Additionally, or alternatively, the additional elements may include collection optics configured to guide onto X-ray detector 504 electromagnetic radiation generated due to the impinging of an e-beam on specimen 50 and penetration of the e-beam thereinto. According to some embodiments, the additional elements may include a filter configured to block electromagnetic radiation outside characteristic X-rays regime and/or one or more subranges thereof.

According to some embodiments, at least e-beam source 502 and stage 520 may be housed within a vacuum chamber 530. While in FIG. 5 X-ray detector 504 is shown positioned inside vacuum chamber 530, according to some alternative embodiments, X-ray detector 504 may be positioned outside vacuum chamber 530.

Controller 508 may be functionally associated with e-beam source 502 and, optionally, stage 520. More specifically, controller 508 is configured to control and synchronize operations and functions of the above-listed instrumentation and components during probing of a tested specimen (e.g., instruct the e-beam source to change the e-beam landing energy).

Processing circuitry 506 may include one or more processors and, optionally, RAM and/or non-volatile memory components (not shown). The one or more processors are configured to execute software instructions stored e.g., in the non-volatile memory components. Through the execution of the software instructions, measurement data (e.g., obtained by X-ray detector 504) of a tested specimen (e.g., specimen 50) is processed to determine \vec{p}ₛ, essentially as described above in the description of FIGS. 1 and 3.

More specifically, processing circuitry 506 is configured to process the measurement data to determine the values (denoted by \vec{p}ₛ) of the one or more structural parameters characterizing the tested specimen, as detailed above in the Methods Subsection. To this end, processing circuitry 506 is configured to extract from the measurement data a vector \vec{f}_{key} specifying values of key features obtained with respect to the tested specimen, as detailed above in the description of suboperation 120b of method 100. In particular, according to some embodiments, the key features include (e.g. are constituted by) the so-called “energy signature”. According to some embodiments, each component of the energy signature may correspond to an absolute, normalized, or relative intensity of a respective characteristic X-ray line.

According to some embodiments, wherein the measurement data are X-ray emission spectra, processing circuitry 506 may be configured to fit onto each of the X-ray emission spectra a respective (free) curve, thereby obtaining an optimized curve. From the optimized curve \vec{f}_{key} may next be extracted, as described above in the description of suboperation 120a of method 100. According to some such embodiments, processing circuitry 506 may be configured to execute one or more optimization algorithms (e.g., to solve the optimization problems specified above in the description of FIGS. 4A-4E). Examples of relevant optimization algorithms include standard iterative optimization algorithms, such as gradient descent or Newton's method. According to some embodiments, customized iterative optimization algorithms, obtained by “tweaking” standard iterative optimization algorithms to account for constraints and/or to assure that a global minimum is attained, can be employed.

More specifically, in order to determine \vec{p}ₛ, processing circuitry 506 is configured to additionally take into account a set of vectors of simulated key features {\vec{f}ₙ}ₙ₌₁^{N}. For each 1≤n≤N, \vec{p}ₙ specifies values of the one or more structural parameters characterizing an n-th simulated specimens. Each of the \vec{f}ₙ may be obtained through computer simulation of emission of X-rays from the respective simulated specimen, due to impinging thereon, one at a time, with e-beams at each of the one or more landing energies, as described above in the Methods Subsection. According to some embodiments, and as expanded on above in the description of method 100, the \vec{p}ₙ sample a hypervolume centered about \vec{p}₀ in a Kₚ dimensional vector space defined by the one or more structural parameters with Kₚ being the number of the one or more structural parameters.

According to some embodiments, processing circuitry 506 may further be configured to obtain {\vec{f}ₙ}ₙ₌₁^{N}, i.e., by simulating the striking of one or more e-beams (one at a time) on each of the N simulated specimens, the penetration of the one or more e-beams thereinto, and the resulting emission of X-rays.

According to some embodiments, processing circuitry 506 may be configured to compute \vec{p}ₛ=(\vec{p}ᵢ)ᵢ₌₁^{k}, wherein the k \vec{p}ᵢ (k<N) label the k \vec{f}ₙ, which are closest to \vec{f}_{key} and the triangular brackets denote averaging, optionally, weighted, over the k \vec{p}ᵢ. To this end, according to some embodiments, processing circuitry 506 may be configured to apply a k-nearest neighbor (k-NN) regression algorithm to \vec{f}_{key} with respect to {\vec{f}ₙ}ₙ₌₁^{N}. According to some embodiments, processing circuitry 506 may be configured to obtain \vec{p}ₛ by computing the median of the \vec{p}ₙ corresponding to the k closest \vec{f}ₙ.

According to some alternative embodiments, \vec{p}ₛ minimizes a loss function, which is a function of at least \vec{f}_{key} and a vector valued function \vec{f}ₑₓₜ(\vec{p}) of the key features that is N extrapolated from {\vec{f}ₙ}ₙ₌₁^{N}. (Optionally, in addition to a first term dependent on \vec{f}_{key} and \vec{f}ₑₓₜ(\vec{p}), the loss function may additionally include one or more regularizing terms.) Accordingly, processing circuitry 506 may be configured to (i) execute an optimization algorithm to minimize over \vec{p} the loss function (e.g. minimize the distance between \vec{f}_{key} and \vec{f}ₑₓₜ(\vec{p})), and (ii) in embodiments wherein the minimization over the loss function has a known analytical solution, additionally, or alternatively, determine \vec{p}ₛ directly from the (function defining the) analytical solution. According to some such embodiments, processing circuitry 506 may be configured to determine \vec{p}ₛ by (numerically or analytically) solving the optimization problem

$${arg min}_{{p}^{→︀}} ‖ {{f}^{→︀}}_{key} - {{f}^{→︀}}_{ext} ( {p}^{→︀} ) ‖ ,$$

or, more generally,

$${arg min}_{{p}^{→︀}} ( {min}_{M} ‖ {{f}^{→︀}}_{key} - M {{f}^{→︀}}_{ext} ( {p}^{→︀} ) ‖ ) ,$$

wherein M is a positive definite matrix (e.g. a diagonal positive definite matrix with pairwise equal diagonal terms as specified above) whose minimum eigenvalue is greater than a prespecified (positive) threshold, and, even more generally,

$${arg min}_{{p}^{→︀}} ( {min}_{{M}_{1} , {M}_{2}} D ( {M}_{1} {{f}^{→︀}}_{key} , {M}_{2} {{f}^{→︀}}_{ext} ( {p}^{→︀} ) ) ) ,$$

wherein M₁ and M₂ are suitably selected matrices and D (M₁\vec{f}_{key}, Mz\vec{f}ₑₓₜ(\vec{p})) is a mathematical distance between M₁\vec{f}_{key} and M₂\vec{f}ₑₓₜ(\vec{p}). \vec{f}ₑₓₜ(\vec{p}) is the vector valued function of the key features (extrapolated from {\vec{f}ₙ}ₙ₌₁^{N}) and models the dependence of the key features on the on the values of the one or more structural parameters.

According to some embodiments, processing circuitry 506 may be further configured to perform the extrapolation (and thereby obtain \vec{f}ₑₓₜ(\vec{p})). According to some such embodiments, the extrapolation may be to a linear function, i.e., \vec{f}ₑₓₜ(\vec{p})=\vec{f}ₑₓₜ(\vec{p}₀+\vec{δ})=\vec{f}₀+A\vec{δ}=\vec{f}₀+A(\vec{p}−\vec{p}₀). \vec{δ} denotes deviations from nominal values \vec{p}₀ of the one or more structural parameters. \vec{f}₀ is a vector of values of the key features corresponding to \vec{p}₀. A is a matrix determinable through optimization, which takes into account the {\vec{f}ₙ}ₙ₌₁^{N}, as detailed above in the description of method 300.

According to some embodiments, processing circuitry 506 may be configured to select the {\vec{f}ₙ}ₙ₌₁^{N} from a larger set {\vec{f}ᵢ}ᵢ₌₁^{N′} (N′>N) by subjecting \vec{f}_{key} to an (k=N)−NN classifier with respect to {\vec{f}ᵢ}ᵢ₌₁^{N′}. As used herein, the terms “fitted” and “optimized” are interchangeable when employed in the context of curve fitting.

According to some embodiments, processing circuitry 506 and controller 508 may be housed in a common housing, for example, when implemented by a single computer.

In the description and claims of the application, the words “include” and “have”, and forms thereof, are not limited to members in a list with which the words may be associated.

As used herein, the term “about” may be used to specify a value of a quantity or parameter (e.g., the length of an element) to within a continuous range of values in the neighborhood of (and including) a given (stated) value. According to some embodiments, “about” may specify the value of a parameter to be between 80% and 120% of the given value. For example, the statement “the length of the element is equal to about 1 m” is equivalent to the statement “the length of the element is between 0.8 m and 1.2 m”. According to some embodiments, “about” may specify the value of a parameter to be between 90% and 110% of the given value. According to some embodiments, “about” may specify the value of a parameter to be between 95% and 105% of the given value.

As used herein, according to some embodiments, the terms “substantially” and “about” may be interchangeable.

According to some embodiments, an estimated quantity or estimated parameter may be said to be “about optimized” or “about optimal” when falling within 5%, 10% or even 20% of the optimal value thereof. Each possibility corresponds to separate embodiments. In particular, the expressions “about optimized” and “about optimal” also cover the case wherein the estimated quantity or estimated parameter is equal to the optimal value of the quantity or the parameter. The optimal value may in principle be obtainable using mathematical optimization software. Thus, for example, an estimated (e.g. an estimated residual) may be said to be “about minimized” or “about minimal/minimum”, when the value thereof is no greater than 101%, 105%, 110%, or 120% (or some other pre-defined threshold percentage) of the optimal value of the quantity. Each possibility corresponds to separate embodiments.

For ease of description, in some of the figures a three-dimensional cartesian coordinate system (with orthogonal axes x, y, and z) is introduced. It is noted that the orientation of the coordinate system relative to a depicted object may vary from one figure to another. Further, the symbol ⊙ may be used to represent an axis pointing “out of the page”, while the symbol ⊗ may be used to represent an axis pointing “into the page”.

In flowcharts, optional operations, and suboperations, are delineated by a dashed line. Similarly, in block diagrams, optional elements may be delineated by a dashed line. Further, (in block diagrams) dotted lines connecting elements may be used to represent functional association or at least one-way or two-way communicational association between the connected elements.

It is appreciated that certain features of the disclosure, which are, for clarity, described in the context of separate embodiments, may also be provided in combination in a single embodiment. Conversely, various features of the disclosure, which are, for brevity, described in the context of a single embodiment, may also be provided separately or in any suitable sub-combination or as suitable in any other described embodiment of the disclosure. No feature described in the context of an embodiment is to be considered an essential feature of that embodiment, unless explicitly specified as such.

Although operations of methods, according to some embodiments, may be described in a specific sequence, the methods of the disclosure may include some or all of the described operations carried out in a different order. In particular, it is to be understood that the order of operations and suboperations of any of the described methods may be reordered unless the context clearly dictates otherwise, for example, when a latter operation requires as input the output of earlier operation or when a latter operation requires the product of an earlier operation. A method of the disclosure may include a few of the operations described or all of the operations described. No particular operation in a disclosed method is to be considered an essential operation of that method, unless explicitly specified as such.

Although the disclosure is described in conjunction with specific embodiments thereof, it is evident that numerous alternatives, modifications, and variations that are apparent to those skilled in the art may exist. Accordingly, the disclosure embraces all such alternatives, modifications, and variations that fall within the scope of the appended claims. It is to be understood that the disclosure is not necessarily limited in its application to the details of construction and the arrangement of the components and/or methods set forth herein. Other embodiments may be practiced, and an embodiment may be carried out in various ways.

The phraseology and terminology employed herein are for descriptive purposes and should not be regarded as limiting. Citation or identification of any reference in this application shall not be construed as an admission that such reference is available as prior art to the disclosure. Section headings are used herein to ease understanding of the specification and should not be construed as necessarily limiting.

What is claimed is:

1. A system for non-destructive characterization of specimens, the system comprising:
an electron beam (e-beam) source for projecting e-beams at one or more e-beam landing energies on a specimen being tested;
an X-ray detector for sensing X-rays emitted from the tested specimen; and
processing circuitry configured to:
receive from the X-ray detector X-ray measurement data pertaining to one or more e-beam landing energies;
extract from the X-ray measurement data a vector \vec{f}_{key} specifying values of key features of the X-ray measurement data; and
determine values \vec{p}ₛ, pertaining to the tested structure and assumed by one or more structural parameters, based on \vec{f}_{key} and a set of vectors of simulated key features {\vec{f}ₙ}ₙ₌₁^{N}, wherein, for each 1≤n≤N, \vec{p}ₙ specifies values pertaining to an n-th simulated specimen and assumed by the one or more structural parameters, and \vec{f}ₙ is a product of computer simulation of emission of X-rays from the n-th simulated specimen due to impinging thereof with e-beams at each of the one or more landing energies.

2. The method of claim 1, wherein \vec{p}ₛ minimizes a loss function, which is a function of at least \vec{f}_{key} and a vector valued function \vec{f}ₑₓₜ(\vec{p}) of the key features, which is extrapolated from {\vec{f}ₙ}ₙ₌₁^{N}.

3. The system of claim 2, wherein the processing circuitry is further configured to determine \vec{p}ₛ by computing a minimum distance between \vec{f}_{key} and \vec{f}ₑₓₜ(\vec{p}).

4. The system of claim 1, wherein the processing circuitry is further configured to determine \vec{p}ₛ by computing distances between \vec{f}_{key} and the \vec{f}ₙ.

5. The system of claim 1, wherein the one or more structural parameters comprise one or more of an overall concentration of at least one material that the tested specimen comprises, and, optionally, when the tested specimen comprises a structure embedded therein or thereon, a width of the embedded structure.

6. The system of claim 1, wherein the tested specimen comprises a plurality of layers; and
wherein the one or more structural parameters comprise one or more of (i) at least one thickness of at least one of the layers, respectively, (ii) a combined thickness of at least two or more of the layers, (iii) at least one mass density of at least one of the layers, respectively, and (vi) at least one relative concentration of at least one material, respectively, in one or more of the layers.

7. The system of claim 1, wherein the one or more e-beam landing energies are such that induced is emission of X-rays about one or more characteristic X-ray lines pertaining to one or more target substances, respectively, which the tested specimen comprises;
wherein the X-ray detector is configured to sense at least one measured spectrum of the respectively emitted X-rays in at least one photon energy range, respectively, which comprises at least one of the characteristic X-ray lines; and
wherein the X-ray measurement data comprises the measured spectra.

8. The system of claim 6, wherein the one or more e-beam landing energies are such that induced is emission of X-rays originating from at least two of the plurality of layers.

9. The system of claim 7, wherein the key features are, comprise, or are functions of intensities of the characteristic X-ray lines and/or intensities of background radiation.

10. The system of claim 2, wherein \vec{f}ₑₓₜ(\vec{p})=\vec{f}ₑₓₜ(\vec{p}₀+\vec{δ})=\vec{f}₀+A\vec{δ} with \vec{p}₀ specifying nominal values of the one or more structural parameters, \vec{δ} specifying deviations from the nominal values, \vec{f}₀ being a vector of values of the key features corresponding to \vec{p}₀, and A being a matrix.

11. The system of claim 10, wherein \vec{f}₀ is a product of computer simulation of emission of X-rays from a simulated specimen, which is characterized by \vec{p}₀, due to impinging thereof with e-beams at each of the one or more landing energies; and
wherein the matrix A equals
$${arg min}_{B} ‖ ( \begin{matrix}{( {{f}_{{{p}_{1}}^{→︀}}}^{→︀} - {{f}^{→︀}}_{0} - B {\vec{δ}}_{1} )}^{T} \\ {( {{f}_{{{p}_{2}}^{→︀}}}^{→︀} - {{f}^{→︀}}_{0} - B {\vec{δ}}_{2} )}^{T} \\ ⋮ \\ {( {{f}_{{{p}_{N}}^{→︀}}}^{→︀} - {{f}^{→︀}}_{0} - B {\vec{δ}}_{N} )}^{T}\end{matrix} ) ‖$$
with the double vertical bars denoting a matrix norm and, for each 1≤n≤N, \hat{δ}ₙ=\vec{p}ₙ−\vec{p}₀.

12. The system of claim 10, wherein \vec{f}₀ and the matrix A are obtained as the solution of
$${arg min}_{\vec{g} , B} ‖ ( \begin{matrix}{( {{f}_{{{p}_{1}}^{→︀}}}^{→︀} - {g}^{→︀} - B {\vec{δ}}_{1} )}^{T} \\ {( {{f}_{{{p}_{2}}^{→︀}}}^{→︀} - {g}^{→︀} - B {\vec{δ}}_{2} )}^{T} \\ ⋮ \\ {( {{f}_{{{p}_{N}}^{→︀}}}^{→︀} - {g}^{→︀} - B {\vec{δ}}_{N} )}^{T}\end{matrix} ) ‖$$
with the double vertical bars denoting a matrix norm and, for each 1≤n≤N, \vec{δ}ₙ=\vec{p}ₙ−\vec{p}₀.

13. The system of claim 4, wherein the processing circuitry is further configured to, as part of determining \vec{p}ₛ, apply a k-nearest neighbor (k-NN) regression algorithm to \vec{f}_{key} with respect to {\vec{f}ₙ}ₙ₌₁^{N} in order to determine k of the \vec{f}ₙ, which are closest to \vec{f}_{key}.

14. The system of claim 13, wherein \vec{p}ₛ is the average, optionally, weighted, or the median of the \vec{p}ₙ corresponding to the k closest \vec{f}ₙ.

15. The system of claim 2, wherein the processing circuitry is further configured to obtain {\vec{f}ₙ}ₙ₌₁^{N} by subjecting \vec{f}_{key} to an (k=N)−NN classifier with respect to a set of N′>N vectors of key features, which comprises the \vec{f}ₙ, and whose other N′−N vectors are obtained by applying the computer simulation with respect to N′−N additional simulated specimens.

16. The system of claim 9, wherein, in order to derive the intensities of the characteristic X-ray lines, the processing circuitry is configured to fit a free curve onto each interval of the measured spectra, which is about centered about a respective characteristic X-ray line and constituted by a vicinity of the characteristic X-ray line, thereby obtaining a respective optimized curve.

17. The system of claim 16, wherein the free curve is a sum of functions, which comprises a bulge-shaped function and a second function, which is a polynomial; and
wherein, the processing circuitry is further configured to, as part of the fitting of the free curve, fit the bulge-shaped function onto a peak about the characteristic X-ray line of the respective measured spectrum, and fit the second function so as to account for a background intensity component of the respective measured spectrum.

18. The system of claim 1, wherein the X-ray detector is an energy-dispersive X-ray spectrometer or a wavelength-dispersive X-ray spectrometer.

19. The system of claim 1, wherein the tested specimen is a patterned wafer, or a part of patterned wafer, optionally, in one of the fabrication stages thereof.

20. A method for non-destructive characterization of specimens, the method comprising:
a measurement operation comprising, for each of one or more landing energies, suboperations of:
projecting an e-beam on a tested specimen; and
obtaining measurement data by measuring intensity of X-rays emitted from the tested specimen due to penetration of the e-beam thereinto; and
a measurement data analysis operation comprising suboperations of:
extracting from the measurement data a vector \vec{f}_{key} specifying values of key features; and
determining values \vec{p}ₛ, pertaining to the tested structure and assumed by one or more structural parameters, based on \vec{f}_{key} and a set of vectors of simulated key features {\vec{f}ₙ}ₙ₌₁^{N}, wherein, for each 1≤n≤N, \vec{p}ₙ specifies values pertaining to an n-th simulated specimen and assumed by one or more structural parameters, and each of the \vec{f}ₙ is obtained through computer simulation of emission of X-rays from the n-th simulated specimen, due to impinging thereof with e-beams at each of the one or more landing energies.
